(19) United States
(12) Patent Application Publication
(10) Pub. No.: US 2026/0026100 A1
(43) Pub. Date: Jan. 22, 2026

(54) SEMICONDUCTOR DEVICE

(71) Applicant: SAMSUNG ELECTRONICS CO., LTD., Suwon-si (KR)

(72) Inventors: Dain Jang, Suwon-si (KR); Kyoungwoo Lee, Suwon-si (KR); Dongmin Kim, Suwon-si (KR); Junggil Yang, Suwon-si (KR)

(73) Assignee: SAMSUNG ELECTRONICS CO., LTD., Suwon-si (KR)

(21) Appl. No.: 19/220,902

(22) Filed: May 28, 2025

(30) Foreign Application Priority Data
Jul. 17, 2024 (KR) 10-2024-0094575

(51) Int. Cl. H10D 84/90; H10D 89/10

(52) U.S. Cl. CPC H10D 84/929; H10D 84/953; H10D 89/10

(57) ABSTRACT

Provided is a semiconductor device including: a first fin structure extending in a vertical direction; a second fin structure extending in the vertical direction, wherein the second fin structure is spaced apart from the first fin structure; an etch stop pattern between the first fin structure and the second fin structure; a lower insulating layer in contact with a lower surface of the first fin structure, a lower surface of the second fin structure and a lower surface of the etch stop pattern; a device isolation layer including an interposed portion on the etch stop pattern, between the first fin structure and the second fin structure; a gate electrode overlapping the interposed portion and the first fin structure; a channel structure overlapping the gate electrode; and a source/drain pattern connected to the channel structure. The etch stop pattern includes a different insulating material from the device isolation layer.

### CROSS-REFERENCE TO RELATED APPLICATION

This application claims priority to Korean Patent Application No. 10-2024-0094575, filed on Jul. 17, 2024, the disclosure of which is hereby incorporated by reference herein in its entirety.

### BACKGROUND

The present disclosure relates to a semiconductor device, and more particularly, to a semiconductor device including an etch stop pattern.

A semiconductor device includes an integrated circuit that includes a metal-oxide-semiconductor field effect transistor (MOSFET). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitation caused by high-integration of the semiconductor device and forming the semiconductor device with more excellent performance is being conducted.

### SUMMARY

One or more embodiments provide a semiconductor device with improved electrical characteristics and reliability, and a method for manufacturing the same.

According to an aspect of an embodiment, a semiconductor device includes: a first fin structure extending in a vertical direction; a second fin structure extending in the vertical direction, wherein the second fin structure is spaced apart from the first fin structure; an etch stop pattern between the first fin structure and the second fin structure; a lower insulating layer in contact with a lower surface of the first fin structure, a lower surface of the second fin structure and a lower surface of the etch stop pattern; a device isolation layer including an interposed portion on the etch stop pattern, between the first fin structure and the second fin structure; a gate electrode overlapping the interposed portion and the first fin structure; a channel structure overlapping the gate electrode; and a source/drain pattern connected to the channel structure. The etch stop pattern includes a different insulating material from the device isolation layer.

According to another aspect of an embodiment, a semiconductor device including: a first fin structure extending in a vertical direction; a second fin structure extending in the vertical direction, wherein the second fin structure is spaced apart from the first fin structure in a first direction; an etch stop pattern between the first fin structure and the second fin structure; a device isolation layer including an interposed portion on the etch stop pattern, between the first fin structure and the second fin structure; a gate electrode overlapping the interposed portion and the first fin structure; a channel structure overlapping the gate electrode; a source/drain pattern on the first fin structure; and a lower active contact connected to the source/drain pattern via the first fin structure. The etch stop pattern includes a different insulating material from the device isolation layer.

According to another aspect of an embodiment, a semiconductor device includes: a lower insulating layer; a lower conductive pattern in the lower insulating layer; a first fin structure and a second fin structure on the lower insulating layer and extending in a vertical direction; an etch stop pattern between the first fin structure and the second fin structure between the first fin structure and the second fin structure; a device isolation layer including an interposed portion on the etch stop pattern, between the first fin structure and the second fin structure; a gate electrode overlapping the interposed portion and the first fin structure; a channel structure overlapping the gate electrode; a source/drain pattern on the first fin structure; and a lower active contact electrically connecting the source/drain pattern and the lower conductive pattern. A lower surface of the first fin structure, a lower surface of the second fin structure and a lower surface of the etch stop pattern are in contact with an upper surface of the lower insulating layer.

### BRIEF DESCRIPTION OF DRAWINGS

The above and other aspects and features will be more apparent from the following description of embodiments, taken in conjunction with the accompanying drawings, in which:

FIGS. 1 and 2 are conceptual views for describing logic cells of a semiconductor device according to some embodiments;

FIG. 3A is a plan view of a semiconductor device according to some embodiments;

FIG. 3B is a cross-sectional view taken along line A-A′ of FIG. 3A;

FIG. 3C is a cross-sectional view taken along line B-B′ of FIG. 3A;

FIG. 3D is a cross-sectional view taken along line C-C′ of FIG. 3A;

FIG. 3E is an enlarged view of region ‘E1’ of FIG. 3B;

FIG. 3F is an enlarged view of region ‘E2’ of FIG. 3C;

FIGS. 4A, 4B, 5-12, 13A, 13B, 13C, 14A, 14B, 15A, 15B, 15C, 16A, 16B, 17A, and 17B are diagrams for describing a method for manufacturing a semiconductor device according to some embodiments;

FIGS. 18A and 18B are cross-sectional views of a semiconductor device according to some embodiments;

FIGS. 19A and 19B are cross-sectional views of a semiconductor device according to some embodiments; and

FIGS. 20A and 20B are enlarged cross-sectional views of a semiconductor device according to some embodiments.

### DETAILED DESCRIPTION

Hereinafter, embodiments will be described in more detail with reference to the accompanying drawings. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

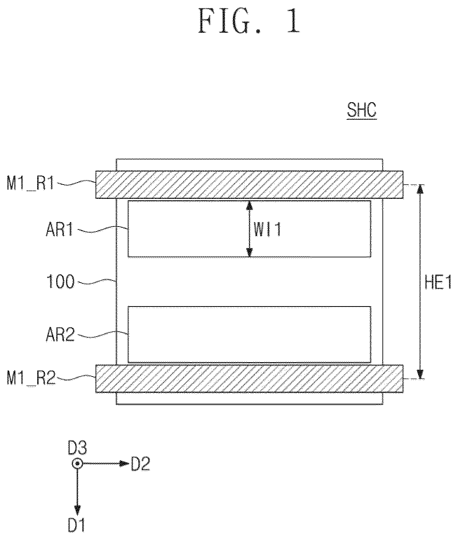

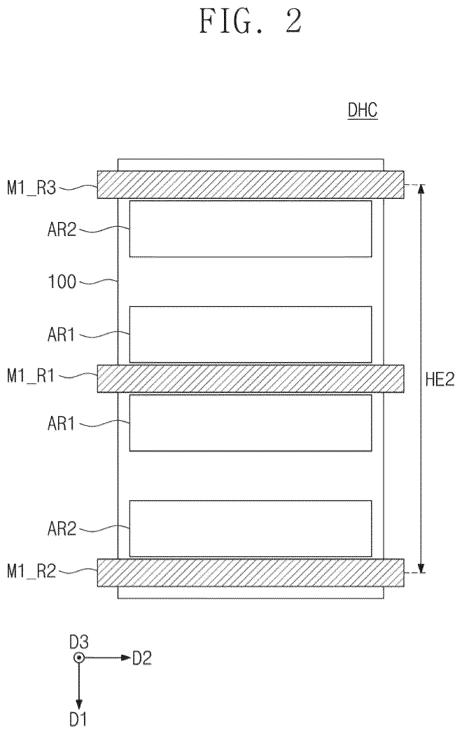

FIGS. 1 and 2 are conceptual views for describing logic cells of a semiconductor device according to some embodiments.

Referring to FIG. 1, a single height cell SHC may be provided. Specifically, a first power line M1_R1 and a second power line M1_R2 may be provided on a substrate 100. The first power line M1_R1 may be a path through which a source voltage VSS is supplied. For example, the first power line M1_R1 may be a path through which a ground voltage is supplied. The second power line M1_R2 may be a path through which a drain voltage VDD is supplied. For example, the second power line M1_R2 may be a path through which a power voltage is supplied.

The single height cell SHC may be defined between the first power line M1_R1 and the second power line M1_R2. The single height cell SHC may include one first active region AR1 and one second active region AR2. One of the first and second active regions AR1 and AR2 may be a p-type metal-oxide-semiconductor field-effect transistor (PMOSFET) region and the other of the first and second active regions AR1 and AR2 may be an n-type metal-oxide-semiconductor field-effect transistor (NMOSFET) region. The single height cell SHC may have a structure of a CMOS provided between the first power line M1_R1 and the second power line M1_R2.

The first and second active regions AR1 and AR2 may each have a first width WII in a first direction D1. A length of the single height cell SHC in the first direction D1 may be defined as a first height HE1. The first height HE may be substantially the same as a distance (for example, a pitch) between the first power line M1_R1 and the second power line M1_R2.

The single height cell SHC may constitute one logic cell. In the present disclosure, a logic cell may refer to a logic device (for example, AND, OR, XOR, XNOR, an inverter, or the like) that performs a specific function. The logic cell may include transistors for constituting the logic device and lines connecting the transistors to each other.

Referring to FIG. 2, a double height cell DHC may be provided. Specifically, a first power line M1_R1, a second power line M1_R2, and a third power line M1_R3 may be provided on the substrate 100. The first power line M1_R1 may be disposed between the second power line M1_R2 and the third power line M1_R3. The third power line M1_R3 may be a path through which a source voltage VSS is supplied.

The double height cell DHC may be defined between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. In a plan view, the first power line M1_R1 may be disposed between the two first active regions AR1.

A length of the double height cell DHC in the first direction D1 may be defined as a second height HE2. The second height HE2 may be about twice the first height HE1 of FIG. 1. The two first active regions AR1 of the double height cell DHC may operate together as one active region.

The double height cell DHC illustrated in FIG. 2 may be defined as a multi-height cell. According to some embodiments, the multi-height cell may include a triple height cell of which a cell height is approximately three times the cell height of the single height cell SHC.

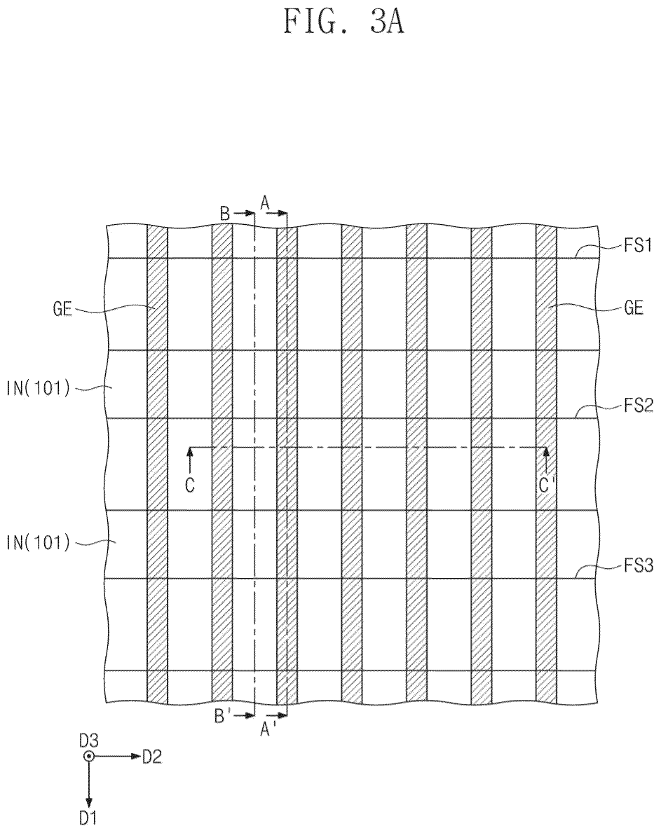

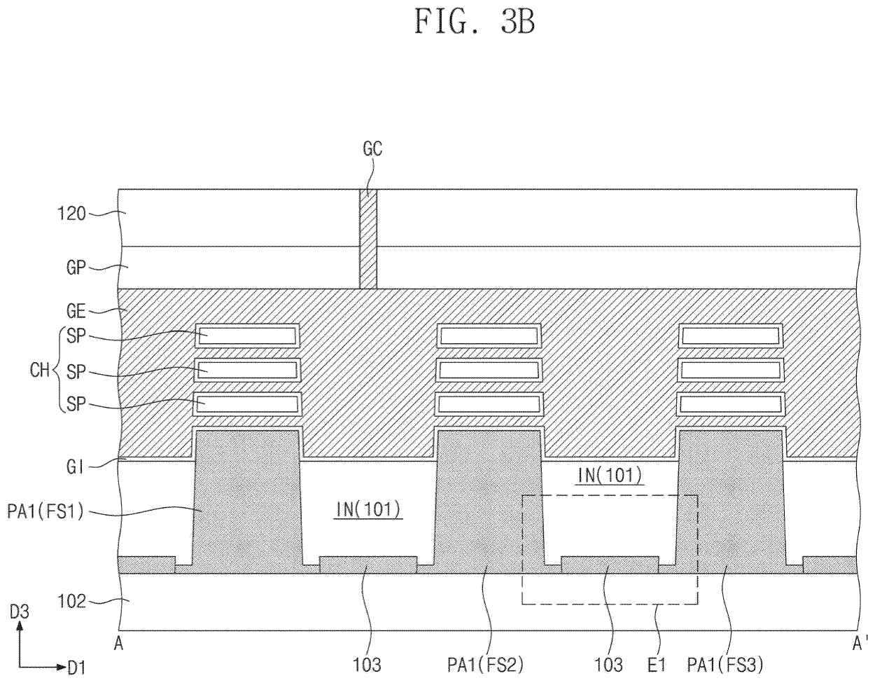

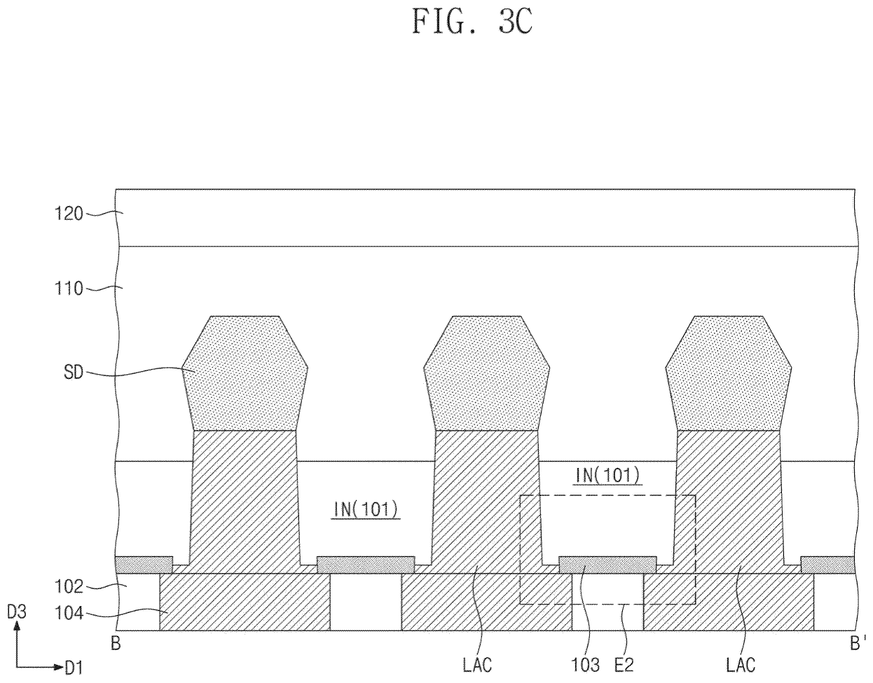

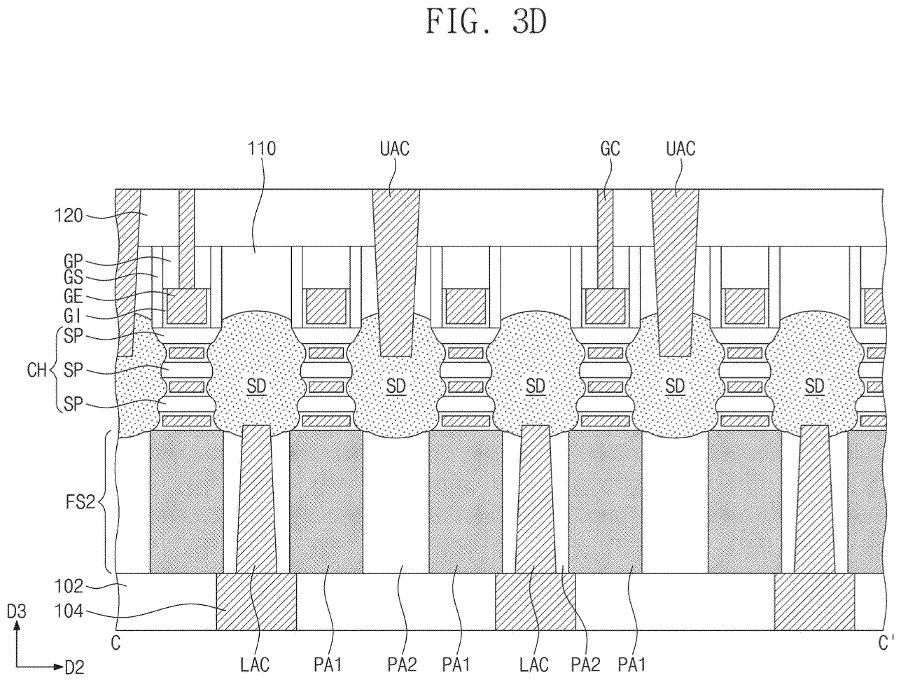

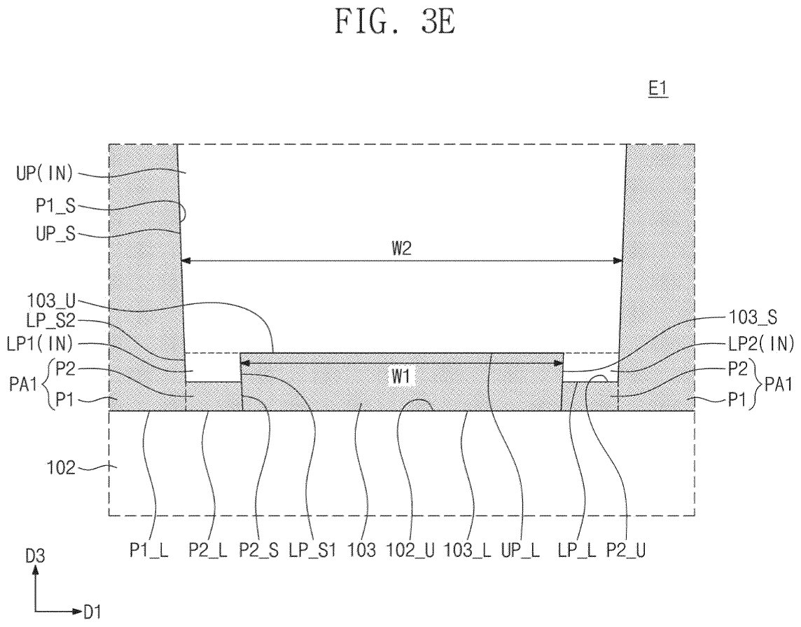

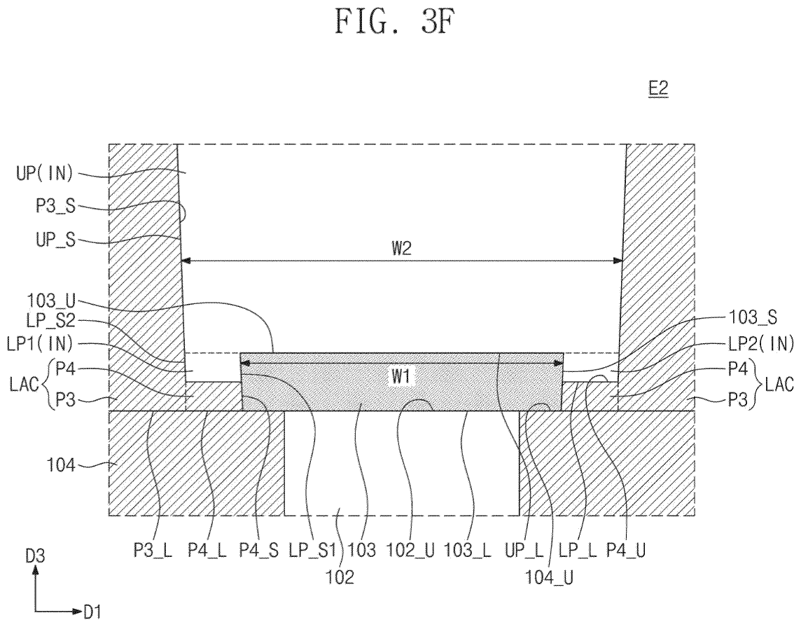

FIG. 3A is a plan view of a semiconductor device according to some embodiments. FIG. 3B is a cross-sectional view taken along line A-A′ of FIG. 3A. FIG. 3C is a cross-sectional view taken along line B-B′ of FIG. 3A. FIG. 3D is a cross-sectional view taken along line C-C′ of FIG. 3A. FIG. 3E is an enlarged view of region ‘E1’ of FIG. 3B. FIG. 3F is an enlarged view of region ‘E2’ of FIG. 3C.

Referring to FIGS. 3A, 3B, 3C and 3D, the semiconductor device may include a lower insulating layer 102. The lower insulating layer 102 may include an insulating material. According to some embodiments, the lower insulating layer 102 may be a multiple layer including a plurality of insulating layers.

The lower insulating layer 102 may have a form of a plate extending along a plane defined by the first direction D1 and a second direction D2. The first direction D1 and the second direction D2 may cross each other. For example, the first direction D1 and the second direction D2 may be horizontal directions perpendicular to each other.

A first fin structure FS1, a second fin structure FS2 and a third fin structure FS3 may be provided on the lower insulating layer 102. The first to third fin structures FS1, FS2 and FS3 may extend in the second direction D2. The first to third fin structures FS1, FS2 and FS3 may be arranged spaced apart from each other in the first direction D1. The second fin structure FS2 may be disposed between the first fin structure FS1 and the third fin structure FS3. The second fin structure FS2 may be adjacent to the first fin structure FS1 and the third fin structure FS3. Lower surfaces of the first to third fin structures FS1, FS2 and FS3 may be in contact with an upper surface of the lower insulating layer 102.

The first to third fin structures FS1, FS2 and FS3 may each include first patterns PA1 and second patterns PA2. The first patterns PA1 and the second patterns PA2 of one of the fin structures FS1, FS2, and FS3 may be alternately arranged along the second direction D2. The first pattern PA1 may be disposed between the second patterns PA2. The second pattern PA2 may be disposed between the first patterns PA1. The first pattern PA1 may overlap a gate electrode GE and a channel structure CH to be described later in a third direction D3. The second patterns PA2 may overlap a source/drain pattern SD to be described later in the third direction D3. The third direction D3 may cross the first direction D1 and the second direction D2. For example, the third direction D3 may be a vertical direction of the first direction D1 and the second direction D2.

The first pattern PA1 may include an insulating material. For example, the first pattern PA1 may include a nitride. The second pattern PA2 may include a different material from the first pattern PA1. The second pattern PA2 may include a semiconductor material. For example, the second patterns PA2 may include silicon. According to some embodiments, the second patterns PA2 may include an insulating material.

Etch stop patterns 103 may be provided on the lower insulating layer 102. The etch stop patterns 103 may extend in the second direction D2. The etch stop patterns 103 may be arranged in the first direction D1. The etch stop patterns 103 and the fin structures FS1, FS2 and FS3 may be alternately arranged in the first direction D1. The etch stop pattern 103 may be disposed between the fin structures FS1, FS2, and FS3. For example, the etch stop pattern 103 may be disposed between the first fin structure FS1 and the second fin structure FS2.

A device isolation layer 101 may be provided on the etch stop patterns 103 and the fin structures FS1, FS2 and FS3. The device isolation layer 101 may surround the fin structures FS1, FS2, and FS3. The device isolation layer 101 may include interposed portions IN between the fin structures FS1, FS2, and FS3. For example, the device isolation layer 101 may include the interposed portion IN between the first fin structure FS1 and the second fin structure FS2. The interposed portion IN may be provided on the etch stop pattern 103. The interposed portion IN may overlap the etch stop pattern 103 in the third direction D3.

The device isolation layer 101 and the etch stop pattern 103 may respectively include different insulating materials. For example, the device isolation layer 101 may include an oxide, and the etch stop patterns 103 may include a nitride. The insulating material included in the device isolation layer 101 may have etching selectivity with respect to the insulating material included in the etch stop pattern 103. According to some embodiments, the etch stop pattern 103 may include a different insulating material from the lower insulating layer 102.

Source/drain patterns SD may be provided on the fin structures FS1, FS2, and FS3. The source/drain patterns SD may each be an epitaxial pattern formed in a selective epitaxial growth (SEG) process. The source/drain patterns SD may include a semiconductor material. For example, the source/drain patterns SD may include at least one of silicon (Si), silicon-germanium (SiGe), or germanium (Ge). The source/drain patterns SD may be doped with an impurity.

Channel structures CH may be provided. The channel structure CH may overlap the fin structure FS1, FS2, and FS3 in the third direction D3. The channel structures CH may be connected to the source/drain pattern SD. The channel structures CH may be disposed between the source/drain patterns SD. The channel structure CH may include semiconductor patterns SP overlapping each other in the third direction D3. The semiconductor patterns SP may include, for example, silicon or silicon-germanium.

Gate electrodes GE may be provided. The gate electrodes GE may overlap the first to third fin structures FS1, FS2 and FS3 and the interposed portions IN of the device isolation layer 101 in the third direction D3. The gate electrodes GE may extend in the first direction D1. The gate electrodes GE may overlap the semiconductor patterns SP of the channel structure CH in the third direction D3. The gate electrodes GE and the semiconductor patterns SP of the channel structure CH may constitute three-dimensional field effect transistors (for example, a multi-bridge channel field effect transistor (MBCFET_ or a gate-all-around field effect transistor (GAAFET)).

According to some embodiments, a gate separation layer that separates the gate electrodes GE may be provided. The gate separation layer may separate the gate electrodes GE such that the gate electrodes GE are spaced apart from each other in the first direction D1.

Gate insulating layers GI may be provided. The gate insulating layers GI may be in contact with the gate electrodes GE, the channel structures CH, the source/drain patterns SD and the fin structures FS1, FS2, and FS3. The gate electrodes GE and the channel structures CH may be spaced apart from each other by the gate insulating layers GI. The gate electrodes GE and the source/drain patterns SD may be spaced apart from each other by the gate insulating layers GI. The gate electrodes GE and the fin structures FS1, FS2, and FS3 may be spaced apart from each other by the gate insulating layers GI. The gate insulating layers GI may include an insulating material. For example, the gate insulating layers GI may include an oxide.

Gate spacers GS may be provided. A pair of the gate spacers GS may be disposed on both sides of the gate electrodes GE. The gate spacers GS may extend in the first direction D1. The upper surfaces of the gate spacers GS may be coplanar with an upper surface of a first interlayer insulating layer 110 to be described later. The gate spacers GS may include an insulating material.

Gate capping patterns GP may be provided. The gate capping patterns GP may be provided on the gate electrodes GE. The gate capping patterns GP may extend in the first direction D1. The gate capping patterns GP may include an insulating material.

The first interlayer insulating layer 110 may be provided. The first interlayer insulating layer 110 may be provided on the source/drain patterns SD and the gate spacers GS. A second interlayer insulating layer 120 may be provided on the first interlayer insulating layer 110. The second interlayer insulating layer 120 may be provided on the first interlayer insulating layer 110, the gate spacers GS and the gate capping patterns GP. The first and second interlayer insulating layers 110 and 120 may include an insulating material. For example, the first and second interlayer insulating layers 110 and 120 may include an oxide.

Upper active contacts UAC and lower active contacts LAC may be provided. The upper active contact UAC and the lower active contact LAC may each be electrically connected to the source/drain pattern SD. The upper active contact UAC may penetrate the first and second interlayer insulating layers 110 and 120 to be connected to an upper portion of the source/drain pattern SD. The lower active contact LAC may penetrate the fin structure FS1, FS2, or FS3 to be connected to a lower portion of the source/drain pattern SD. The lower active contact LAC may penetrate the second pattern PA2. A lower surface of the lower active contact LAC may be in contact with an upper surface of the lower insulating layer 102. The upper active contact UAC and the lower active contact LAC may include a conductive material.

Gate contacts GC may be provided. The gate contacts GC may be electrically connected to the gate electrode GE. The gate contacts GC may penetrate the second interlayer insulating layer 120 and the gate capping pattern GP. The gate contacts GC may include a conductive material.

Lower conductive patterns 104 may be provided in the lower insulating layer 102. The lower conductive pattern 104 may be electrically connected to the lower active contact LAC. The lower conductive patterns 104 may include a conductive material.

The etch stop pattern 103 and the interposed portion IN of the device isolation layer 101 may extend in the second direction D2. The etch stop pattern 103 and the interposed portion IN of the device isolation layer 101 may be in contact with the first patterns PA1, the second patterns PA2 and the lower active contacts LAC arranged in the second direction D2.

Referring to FIGS. 3E and 3F, the interposed portion IN of the device isolation layer 101 may include a first lower portion LP1, a second lower portion LP2 and an upper portion UP. The upper portion UP of the interposed portion IN may be disposed at a higher level than the first lower portion LP1 and the second lower portion LP2 of the interposed portion IN. A lower surface UP_L of the upper portion UP of the interposed portion IN may be in contact with an upper surface 103_U of the etch stop pattern 103. The etch stop pattern 103 may be disposed between the first and second lower portions LP1 and LP2 of the interposed portion IN. The first and second lower portions LP1 and LP2 of the interposed portion IN may be disposed at the same level as the etch stop pattern 103. The first and second lower portions LP1 and LP2 of the interposed portion IN may be disposed at a lower level than the upper surface 103_U of the etch stop pattern 103. The upper portion UP of the interposed portion IN may be disposed at a higher level than the upper surface 103_U of the etch stop pattern 103. A level of a boundary of the first and second lower portions LP1 and LP2 and the upper portion UP of the interposed portion IN may be the same as a level of the upper surface 103_U of the etch stop pattern 103.

A first sidewall LP_S1 of each of the first and second lower portions LP1 and LP2 of the interposed portion IN may be in contact with a sidewall 103_S of the etch stop pattern 103. A second sidewall LP_S2 of each of the first and second lower portions LP1 and LP2 of the interposed portion IN may be in contact with the first pattern PA1, the second pattern PA2 and the lower active contact LAC.

The first pattern PA1 may include a first part P1 and a second part P2. The second part P2 of the first pattern PA1 may protrude from the first part P1 of the first pattern PA1 in the first direction D1 or an opposite direction of the first direction D1. The lower active contacts LAC may include a first part P3 and second parts P4. The second part P4 of the lower active contacts LAC may protrude from the first part P3 of the lower active contacts LAC in the first direction D1 or an opposite direction of the first direction D1. According to some embodiments, similarly to the first pattern PA1, the second pattern PA2 may include a first part and a second part.

The second part P2 of the first pattern PA1 may be disposed between the etch stop pattern 103 and the first part P1 of the first pattern PA1. The second part P2 of the first pattern PA1 may be disposed between the lower portion LP1 or LP2 of the interposed portion IN and the lower insulating layer 102. The second part P4 of the lower active contact LAC may be disposed between the etch stop pattern 103 and the first part P3 of the lower active contact LAC. The second part P4 of the lower active contact LAC may be disposed between the lower portion LP1 or LP2 of the interposed portion IN and the lower insulating layer 102. The etch stop pattern 103 may be disposed between the second parts P2 of the first patterns PA1 adjacent to each other in the first direction D1. The etch stop pattern 103 may be disposed between the second parts P4 of the lower active contacts LAC adjacent to each other in the first direction D1.

A level of a lower surface LP_L of each of the first and second lower portions LP1 and LP2 of the interposed portion IN may be higher than a level of a lower surface 103_L of the etch stop pattern 103. The lower surface LP_L of each of the first and second lower portions LP1 and LP2 of the interposed portion IN may be in contact with an upper surface P2_U of the second part P2 of the first pattern PA1 and an upper surface P4_U of the second parts P4 of the lower active contact LAC. The second sidewalls LP_S2 of each of the first and second lower portions LP1 and LP2 of the interposed portion IN may be in contact with a sidewall P1_S of the first part P1 of the first pattern PA1 and a sidewalls P3_S of the first part P3 of the lower active contact LAC. A sidewall UP_S of the upper portion UP of the interposed portion IN may be in contact with a sidewall P1_S of the first part P1 of the first pattern PA1 and a sidewall P3_S of the first part P3 of the lower active contact LAC. A second sidewall LP_S2 of each of the first and second lower portions LP1 and LP2 of the interposed portion IN may be coplanar with the sidewall UP_S of the upper portion UP of the interposed portion IN.

A sidewall P2_S of the second part P2 of the first pattern PA1 may be in contact with the sidewall 103_S of the etch stop pattern 103. A sidewall P4_S of the second part P4 of the lower active contacts LAC may be in contact with the sidewall 103_S of the etch stop pattern 103. The sidewall P2_S of the second part P2 of the first pattern PA1, the sidewall P4_S of the second part P4 of the lower active contact LAC and the first sidewall LP_S1 of the lower portion LP1 or LP2 of the interposed portion IN may be coplanar with each other. The sidewall P2_S of the second part P2 of the first pattern PA1, and the sidewall P4_S of the second part P4 of the lower active contact LAC may be connected to the first sidewall LP_S1 of the lower portion LP1 or LP2 of the interposed portion IN.

A sum of a length in the third direction D3 of the sidewall P2_S of the second part P2 of the first pattern PA1 and a length in the third direction D3 of the first sidewall LP_S1 of the lower portion LP1 or LP2 of the interposed portion IN may be the same as a length in the third direction D3 of the sidewall 103_S of the etch stop pattern 103.

A sum of a length in the third direction D3 of the sidewall P4_S of the second part P4 of the first pattern LAC and a length in the third direction D3 of the first sidewall LP_S1 of the lower portion LP1 or LP2 of the interposed portion IN may be the same as a length in the third direction D3 of the sidewall 103_S of the etch stop pattern 103.

A lower surface P1_L of the first part P1 of the first pattern PA1, a lower surface P2_L of the second part P2 of the first pattern PA1, a lower surface P3_L of the first part P3 of the lower active contact LAC, a lower surface P4_L of the second part P4 of the lower active contact LAC and the lower surface 103_L of the etch stop pattern 103 may be coplanar with each other. The lower surface P1_L of the first part P1 of the first pattern PA1, the lower surface P2_L of the second part P2 of the first pattern PA1 and the lower surface 103_L of the etch stop pattern 103 may be in contact with an upper surface 102_U of the lower insulating layer 102. The lower surface P3_L of the first part P3 of the lower active contacts LAC, the lower surface P4_L of the second part P4 of the lower active contacts LAC and the lower surface 103_L of the etch stop pattern 103 may be in contact with an upper surface 104_U of the lower conductive pattern 104. A lower surface of each of the first to third fin structures FS1, FS2 and FS3 may include a lower surface P1_L of the first part P1 of the first pattern PA1, a lower surface P2_L of the second part P2 of the first pattern PA1 and a lower surface of the second pattern PA2 The lower surface of each of the first to third fin structures FS1, FS2 and FS3 may be in contact with an upper surface 102_U of the lower insulating layer 102.

A width W1 in the first direction D1 of the etch stop pattern 103 may be narrower than a width W2 in the first direction D1 of the interposed portion IN.

Because the semiconductor device according to some embodiments includes the etch stop pattern 103, the interposed portion IN of the device isolation layer 101 may be protected. The interposed portion IN of the device isolation layer 101 may be protected, and thus reliability of the semiconductor device may be improved.

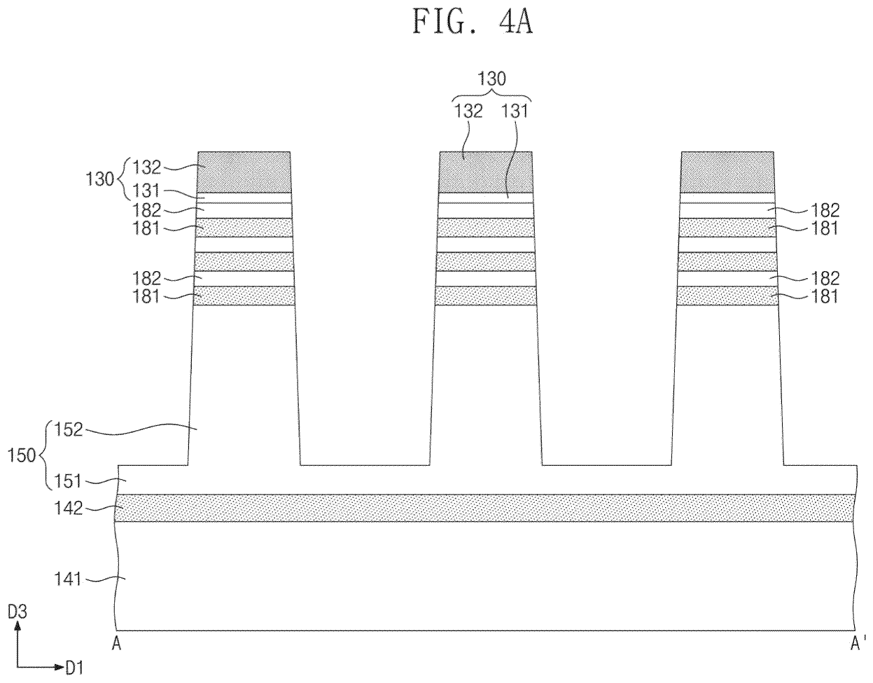

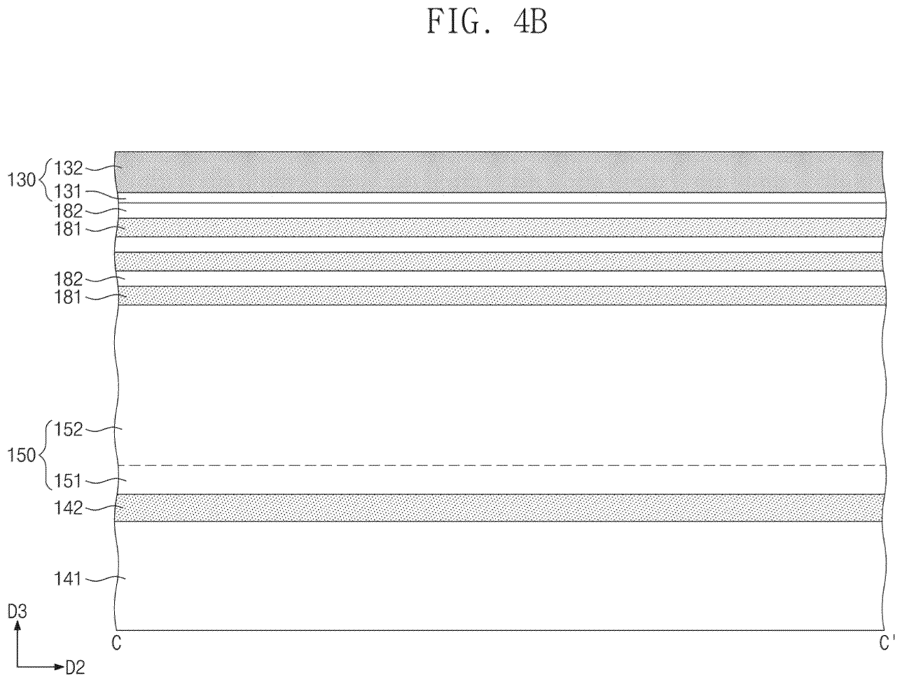

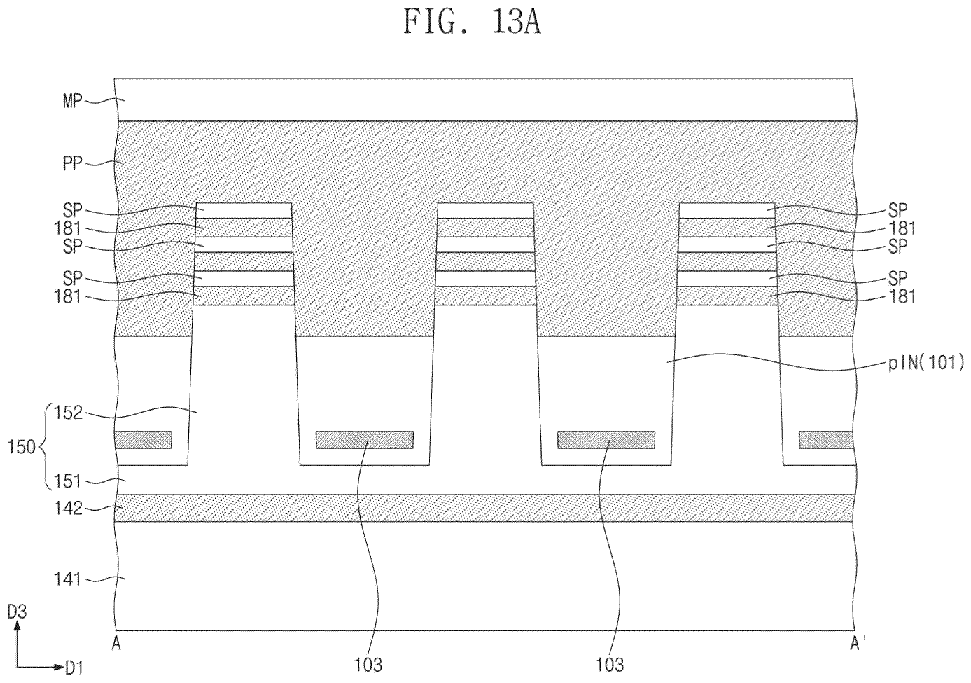

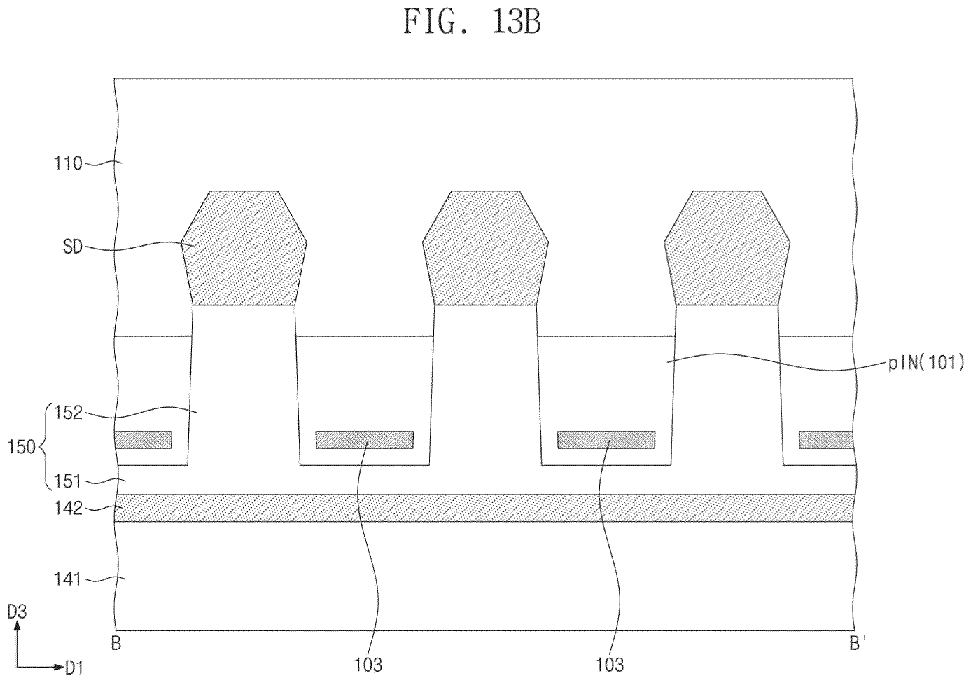

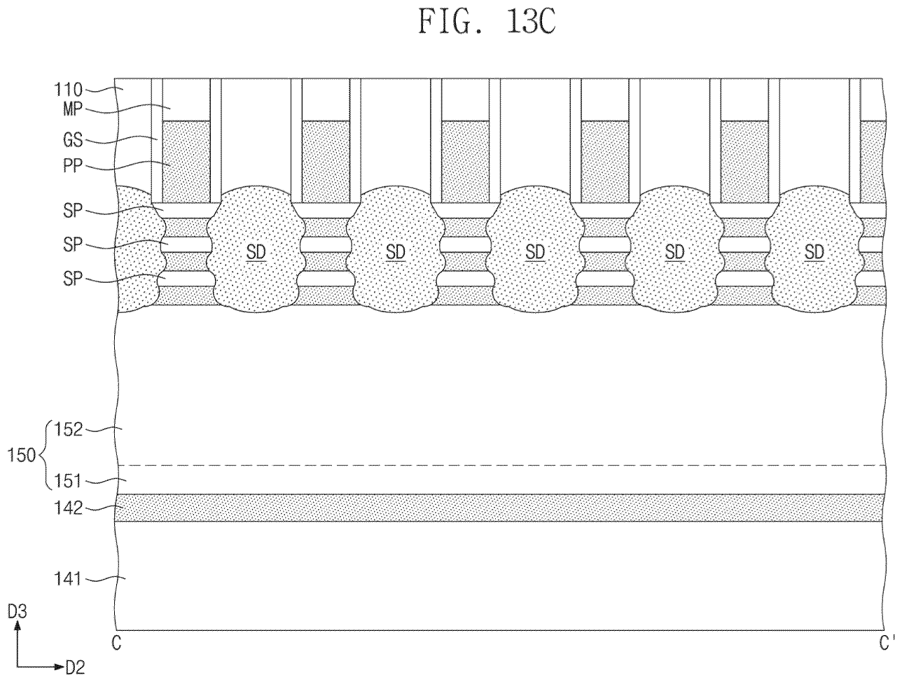

FIGS. 4A, 4B, 5-12, 13A, 13B, 13C, 14A, 14B, 15A, 15B, 15C, 16A, 16B, 17A, and 17B are diagrams for describing a method for manufacturing a semiconductor device according to some embodiments. FIGS. 4A, 5-12, 13A, 14A, 15A, 16A and 17A show cross-sectional views of the method for manufacturing a semiconductor device according to an embodiments with respect to line A-A′ of FIG. 3A. FIGS. 13B, 15B, 16B and 17B show cross-sectional views of the method for manufacturing a semiconductor device according to an embodiments with respect to line B-B′ of FIG. 3A. FIGS. 4B, 13C, 14B and 15C show cross-sectional views of the method for manufacturing a semiconductor device according to an embodiments with respect to line C-C′ of FIG. 3A.

Referring to FIGS. 4A and 4B, a first sacrificial substrate 141, a second sacrificial substrate 142, and a substrate 150 may be formed. The second sacrificial substrate 142 may be formed on the first sacrificial substrate 141. The substrate 150 may be formed on the second sacrificial substrate 142. The second sacrificial substrate 142 may include a different material from the first sacrificial substrate 141 and the substrate 150. For example, the first sacrificial substrate 141 and the substrate 150 may include silicon, and the second sacrificial substrate 142 may include silicon-germanium. According to some embodiments, the substrate 150 may be provided without the first sacrificial substrate 141 and the second sacrificial substrate 142.

Fin patterns 152, sacrificial layers 181, semiconductor layers 182 and mask structures 130 may be formed. Forming the fin patterns 152, the sacrificial layers 181, the semiconductor layers 182 and the mask structures 130 may include alternately forming preliminary sacrificial layers and preliminary semiconductor layers on the substrate 150, forming the mask structures 130, and patterning the preliminary sacrificial layers, the preliminary semiconductor layers and the substrate 150 by using the mask structures 130 as etching masks.

The mask structure 130 may include a first mask pattern 131 and a second mask pattern 132 on the first mask pattern 131. The first mask pattern 131 and the second mask pattern 132 may include different insulating materials. For example, the first mask pattern 131 may include an oxide, and the second mask pattern 132 may include a nitride.

The sacrificial layers 181 may be formed by patterning the preliminary sacrificial layers. The semiconductor layers 182 may be formed by patterning the preliminary semiconductor layers. The fin patterns 152 and a lower portion 151 of the substrate 150 may be formed by patterning the substrate 150. The fin patterns 152 may protrude from the substrate 150 in the third direction D3. The fin patterns 152 may extend in the second direction D2. The lower portion 151 of the substrate 150 may have a form of a plate extending along a plane defined by the first direction D1 and the second direction D2.

The sacrificial layers 181 may include a material having etching selectivity for the semiconductor layers 182. For example, the sacrificial layers 181 may include silicon-germanium, and the semiconductor layers 182 may include silicon.

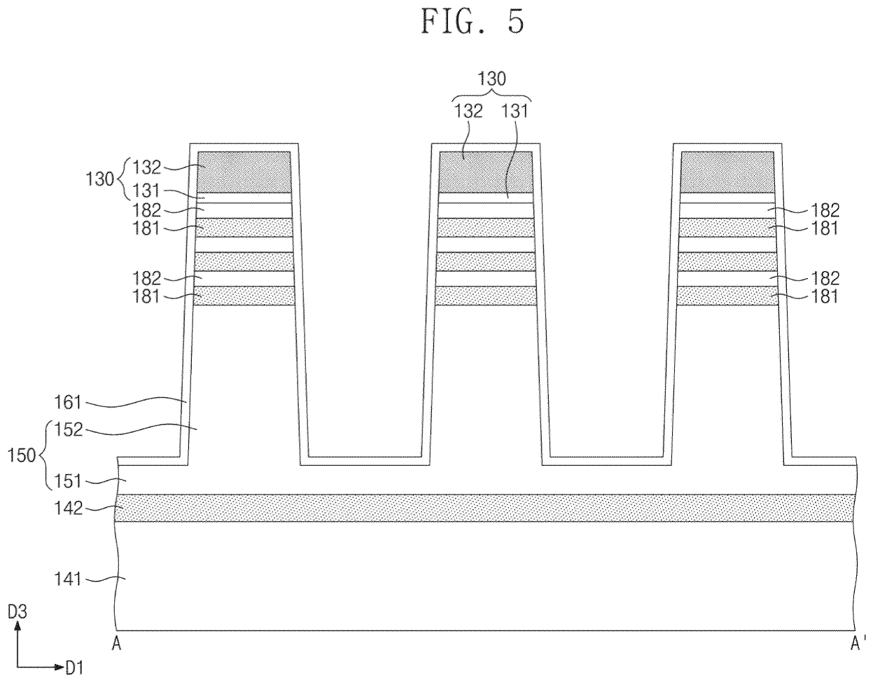

Referring to FIG. 5, a first material layer 161 may be formed on the substrate 150, the sacrificial layers 181, the semiconductor layers 182 and the mask structures 130. The first material layer 161 may include a semiconductor material. For example, the first material layer 161 may include silicon. According to some embodiments, portions, on the substrate 150, the sacrificial layers 181 and the semiconductor layers 182, of the first material layer 161 may include single-crystalline silicon, and a portion, on the mask structure 130, of the first material layer 161 may include polysilicon. According to some embodiments, the first material layer 161 may be formed through an epitaxial growth method.

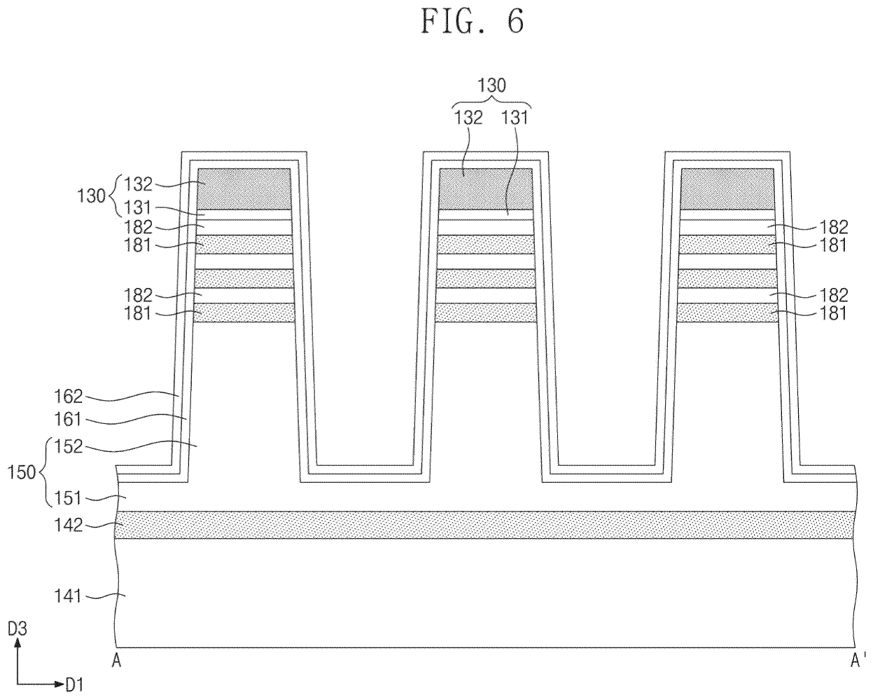

Referring to FIG. 6, a second material layer 162 may be formed on the first material layer 161. The second material layer 162 may include an insulating material. For example, the second material layer 162 may include an oxide. According to some embodiments, the second material layer 162 may be formed by supplying an oxygen gas onto the first material layer 161. In this case, the second material layer 162 may be formed by oxidizing the first material layer 161.

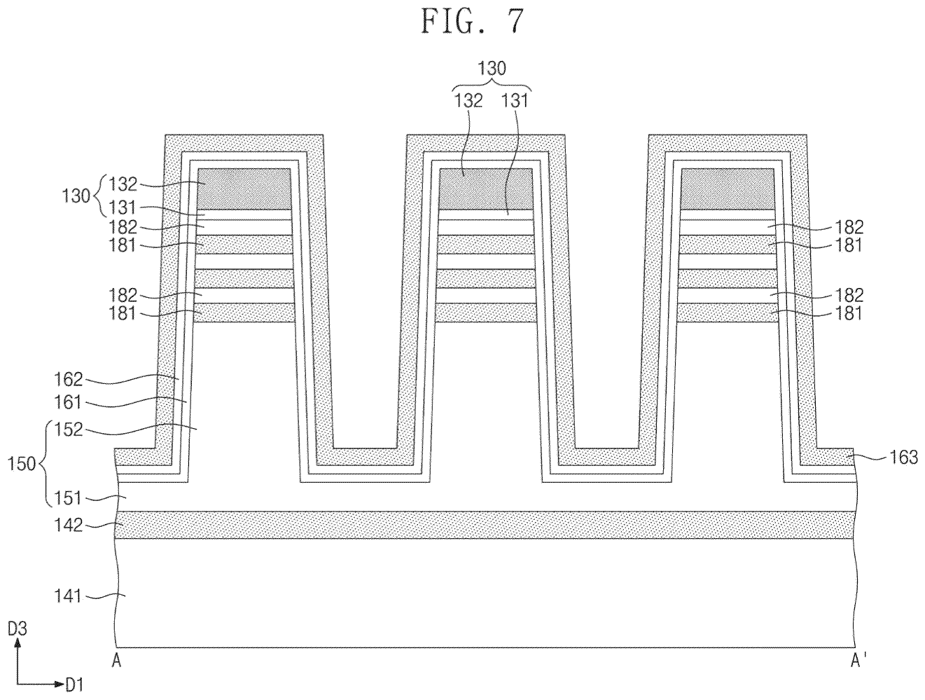

Referring to FIG. 7, a preliminary etch stop layer 163 may be formed on the second material layer 162. The preliminary etch stop layer 163 may include an insulating material. For example, the preliminary etch stop layer 163 may include silicon nitride. According to some embodiments, the preliminary etch stop layer 163 may be formed through a deposition process. The preliminary etch stop layer 163 may have a thickness of, for example, about 5 nm.

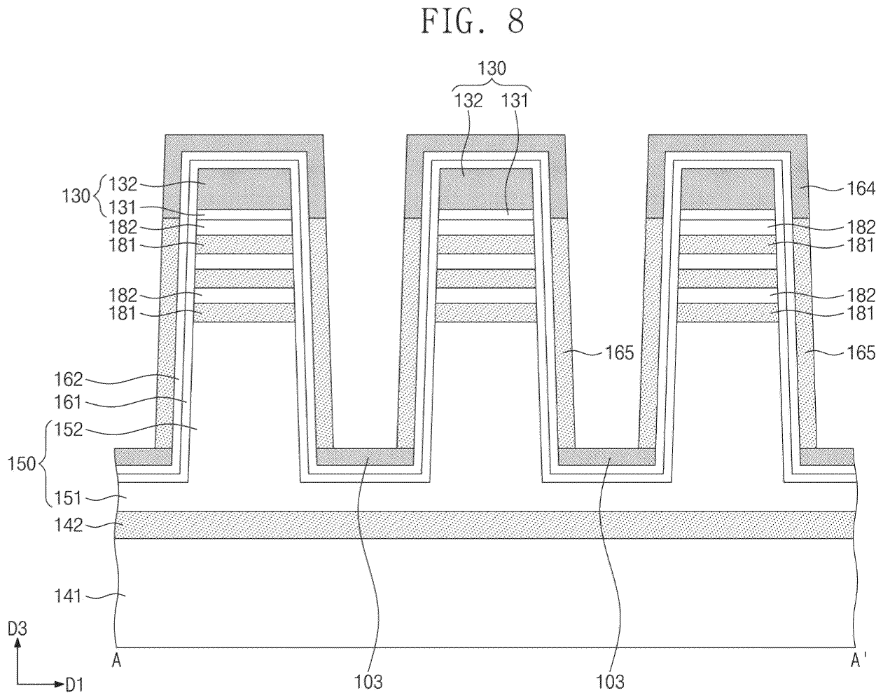

Referring to FIG. 8, a curing process of the preliminary etch stop layer 163 may be performed. Etch stop patterns 103, first preliminary patterns 164 and second preliminary patterns 165 may be formed by performing the curing process. The etch stop patterns 103 and the first preliminary patterns 164 may be portions of the preliminary etch stop layer 163 cured through the curing process. The second preliminary patterns 165 may be portions of the preliminary etch stop layer 163 not cured through the curing process.

The second preliminary pattern 165 may be disposed between the etch stop pattern 103 and the first preliminary pattern 164. The second preliminary pattern 165 may connect the etch stop pattern 103 and the first preliminary pattern 164. The first preliminary pattern 164 may be disposed at the same level as the mask structure 130. The second preliminary pattern 165 may be disposed at the same level as the sacrificial layer 181 and the semiconductor layer 182. The etch stop patterns 103 may be disposed at a lower level than the sacrificial layer 181 and the semiconductor layer 182.

A binding force between materials included in the etch stop pattern 103 may be greater than a binding force between materials included in the second preliminary pattern 165. A number of interatomic bonding per unit volume (for example, a covalent bonding, an ionic bonding, or a metallic bonding) of the etch stop pattern 103 may be greater than a number of interatomic bonding per unit volume of the second preliminary pattern 165. For example, the etch stop pattern 103 and the second preliminary pattern 165 may include nitrogen and silicon, and the etch stop pattern 103 may have a greater number of bonding of nitrogen and silicon per unit volume than the second preliminary pattern 165.

A binding force between materials included in the first preliminary pattern 164 may be greater than a binding force between materials included in the second preliminary pattern 165. A number of interatomic bonding per unit volume of the first preliminary pattern 164 may be greater than a number of interatomic bonding per unit volume of the second preliminary pattern 165. For example, the first preliminary pattern 164 and the second preliminary pattern 165 may include nitrogen and silicon, and the first preliminary pattern 164 may have a greater number of bonding of nitrogen and silicon per unit volume than the second preliminary pattern 165.

According to some embodiments, the curing process of the preliminary etch stop layer 163 may include forming plasma and infiltrating ions of the plasma into the preliminary etch stop layer 163. For example, nitrogen plasma may be formed, and nitrogen ions may be infiltrated into the preliminary etch stop layer 163.

Portions, of the preliminary etch stop layer 163, into which the ions are infiltrated may be cured. For example, the nitrogen ions may be infiltrated into the preliminary etch stop layer 163, and nitrogen and silicon of the portions, of the preliminary etch stop layer 163, into which the nitrogen ions are infiltrated may be bonded by the nitrogen ion.

The ions of the plasma may be anisotropically infiltrated into the preliminary etch stop layer 163. For example, the ions of the plasma may be infiltrated into the preliminary etch stop layer 163 in an opposite direction of the third direction D3, and the etch stop pattern 103 and the first preliminary pattern 164 may be formed.

The second material layer 162 may block a material included in the preliminary etch stop layer 163 and the ions of the plasma from diffusing to the first material layer 161, the semiconductor layer 182 and the substrate 150. For example, the second material layer 162 may block nitrogen included in the preliminary etch stop layer 163 and the nitrogen ions of the plasma from diffusing to the first material layer 161, the semiconductor layer 182 and the substrate 150. The second material layer 162 may include a different insulating material from the preliminary etch stop layer 163.

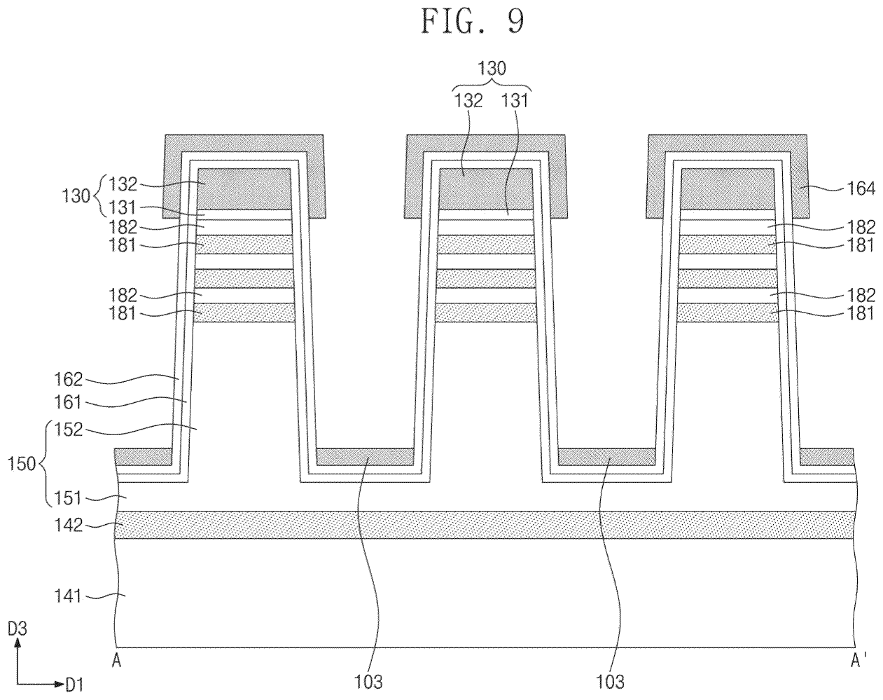

Referring to FIG. 9, the second preliminary patterns 165 may be removed.

According to some embodiments, the second preliminary patterns 165 may be selectively removed by supplying an etching material (for example, HF) on the etch stop patterns 103, the first preliminary patterns 164 and the second preliminary patterns 165.

According to some embodiments, because a binding force of materials included in the second preliminary patterns 165 is weaker than a binding force of materials included in the first preliminary patterns 164 and a binding force of materials included in the etch stop patterns 103, the second preliminary patterns 165 may be selectively removed. According to some embodiments, because a number of interatomic bonding per unit volume of the second preliminary pattern 165 is less than a number of interatomic bonding per unit volume of the first preliminary pattern 164 and a number of interatomic bonding per unit volume of the etch stop pattern 103, the second preliminary pattern 165 may be selectively removed.

The second material layer 162 may be exposed by removing the second preliminary patterns 165.

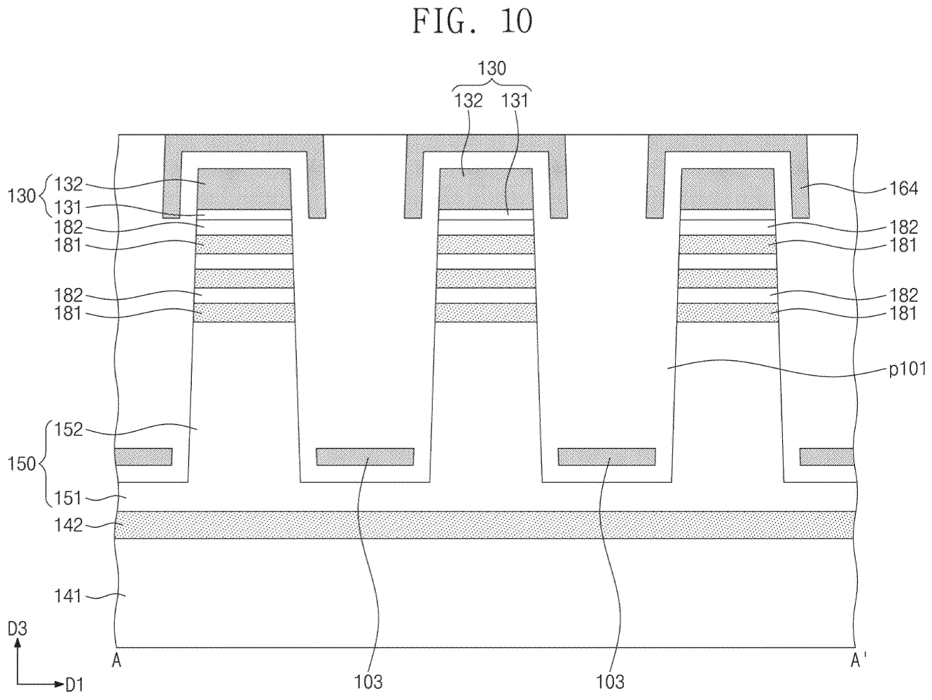

Referring to FIG. 10, a preliminary device isolation layer p101 may be formed. According to some embodiments, forming the preliminary device isolation layer p101 may include depositing an oxide on the etch stop patterns 103, the second material layer 162 and the first preliminary patterns 164. The first material layer 161 may be oxidized by the oxide deposited on the second material layer 162. The preliminary device isolation layer p101 may include the second material layer 162 and the oxidized first material layer 161.

The preliminary device isolation layer p101 may surround the first preliminary patterns 164, the etch stop patterns 103, the fin patterns 152, the sacrificial layers 181, the semiconductor layers 182 and the mask structures 130. The preliminary device isolation layer p101 may be in contact with an upper surface, a lower surface and sidewalls of the etch stop pattern 103.

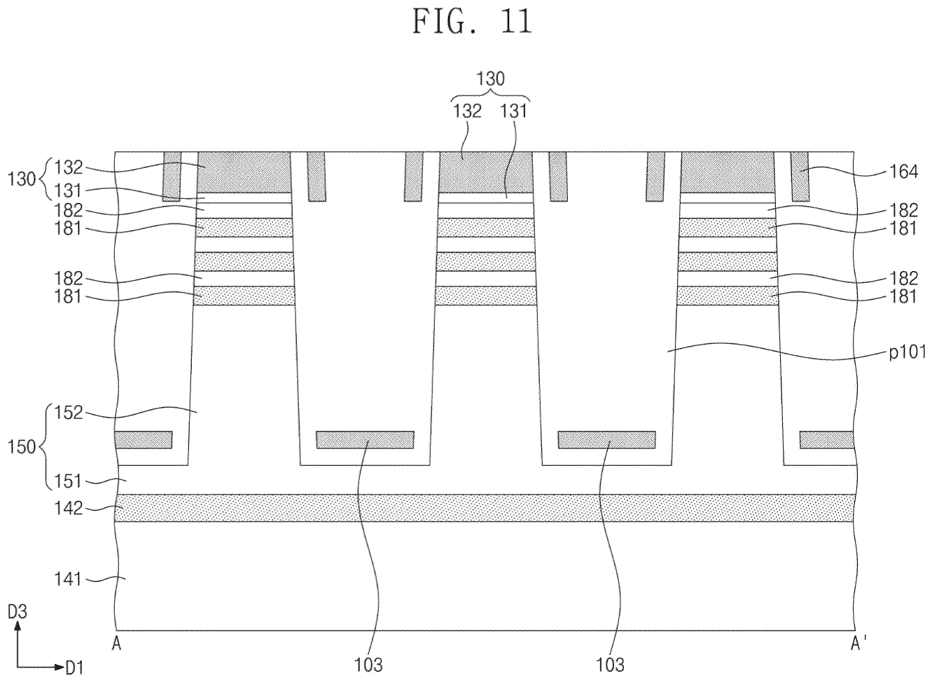

Referring to FIG. 11, an upper portion of the preliminary device isolation layer p101 and upper portions of the first preliminary patterns 164 may be removed. The upper portion of the preliminary device isolation layer p101 and the upper portions of the first preliminary patterns 164 may be removed by, for example, a chemical mechanical polishing (CMP) process.

The upper portion of the preliminary device isolation layer p101 and the upper portions of the first preliminary patterns 164 may be removed to expose an upper surface of the second mask pattern 132 of the mask structure 130.

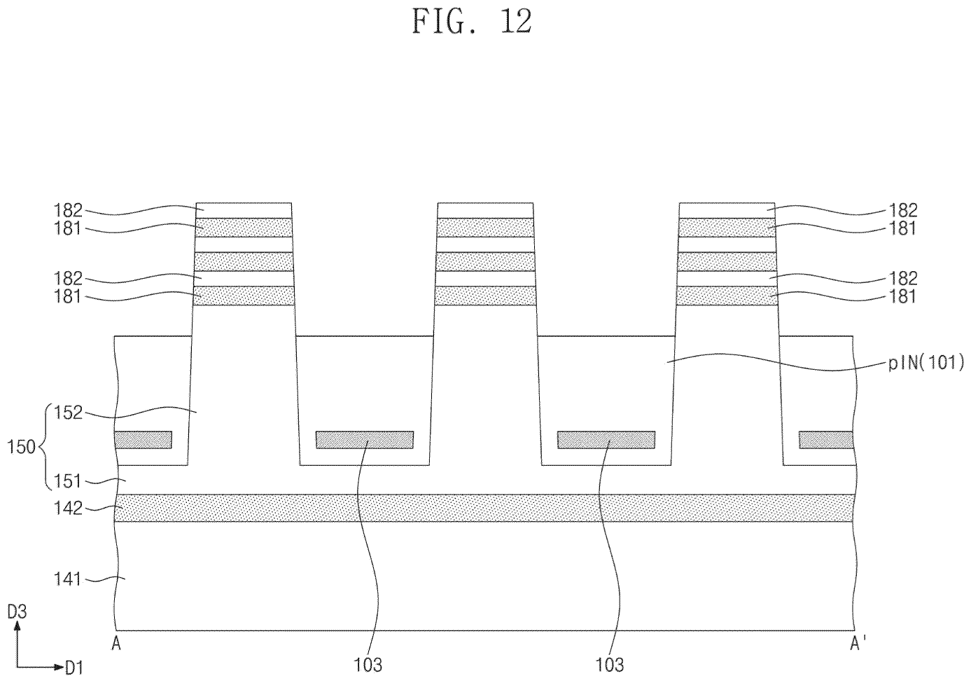

Referring to FIG. 12, the mask structures 130 and the first preliminary patterns 164 may be removed. The preliminary device isolation layer p101 may be etched. The etched preliminary device isolation layer p101 may be defined as a device isolation layer 101. The device isolation layer 101 may include a preliminary interposed portion pIN between the fin patterns 152.

The preliminary device isolation layer p101 may be etched to expose the sacrificial layers 181 and the semiconductor layers 182.

Referring to FIGS. 13A, 13B and 13C, sacrificial patterns PP and mask patterns MP may be formed. Forming the sacrificial patterns PP and the mask patterns MP may include forming a preliminary sacrificial pattern layer, forming the mask patterns MP on the preliminary sacrificial pattern layer, and patterning the preliminary sacrificial pattern layer by using the mask patterns MP as etching masks. The sacrificial patterns PP may be formed by patterning the preliminary sacrificial pattern layer.

The sacrificial patterns PP may be formed on the semiconductor layers 182, the sacrificial layers 181 and the preliminary interposed portions pIN of the device isolation layer 101. For example, the sacrificial patterns PP may include polysilicon. The mask patterns MP may include an insulating material.

Gate spacers GS may be formed. The gate spacers GS may be formed on sidewalls of the sacrificial pattern PP and the mask pattern MP.

The sacrificial layers 181 and the semiconductor layers 182 may be etched by using the mask patterns MP and the gate spacers GS as etching masks. The semiconductor patterns SP may be formed by etching the semiconductor layers 182. The semiconductor layer 182 may be divided into the semiconductor patterns SP arranged in the second direction D2.

Source/drain patterns SD may be formed. The source/drain patterns SD may be formed through an epitaxial growth process by using the semiconductor patterns SP and the etched sacrificial layers 181 as seeds. A first interlayer insulating layer 110 may be formed on the source/drain patterns SD.

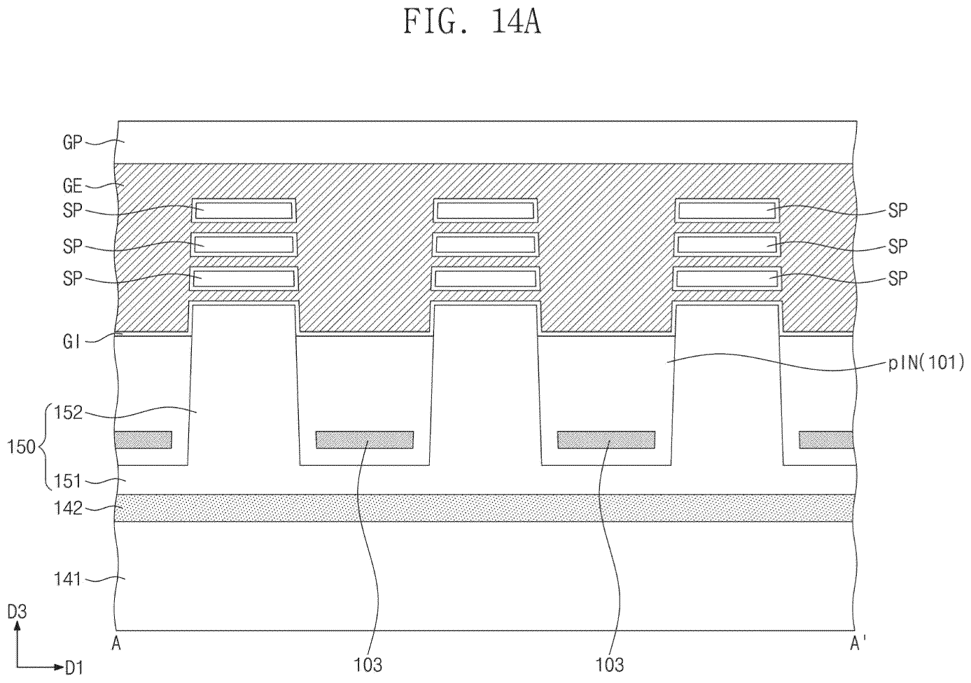

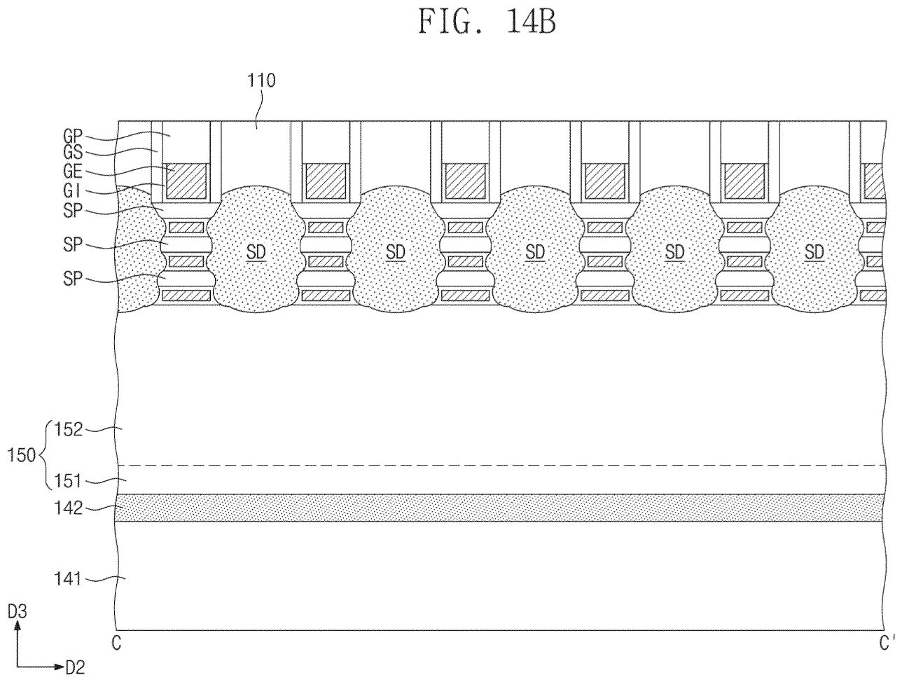

Referring to FIGS. 14A and 14B, the sacrificial layers 181, the mask patterns MP and the sacrificial patterns PP may be removed. Gate insulating layers GI, gate electrodes GE and gate capping patterns GP may be formed in empty spaces formed by removing the sacrificial layers 181, the mask patterns MP and the sacrificial patterns PP.

The gate insulating layer GI may be formed on the semiconductor patterns SP and the preliminary interposed portions pIN of the device isolation layer 101. The gate electrode GE may be formed on the gate insulating layer GI. The gate capping pattern GP may be formed on the gate electrode GE.

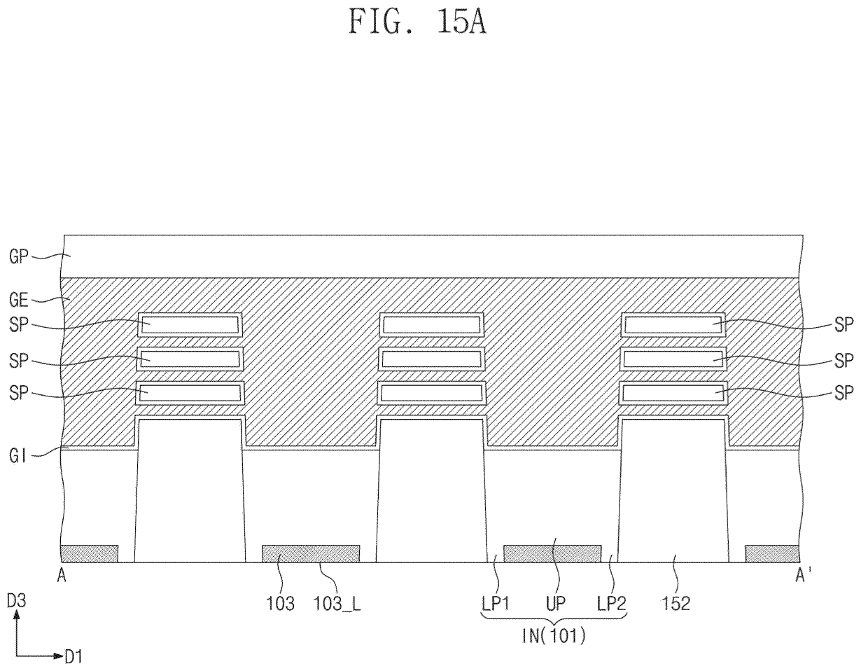

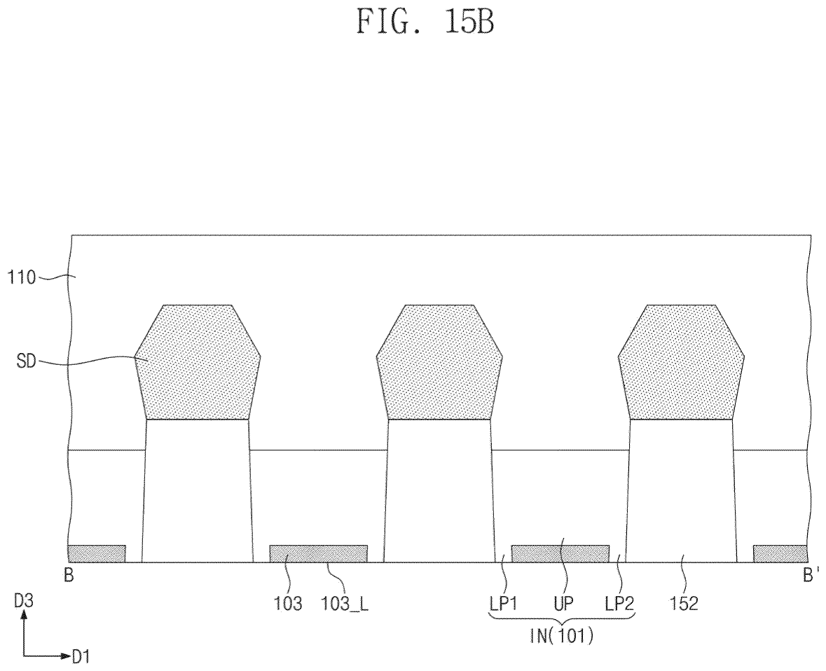

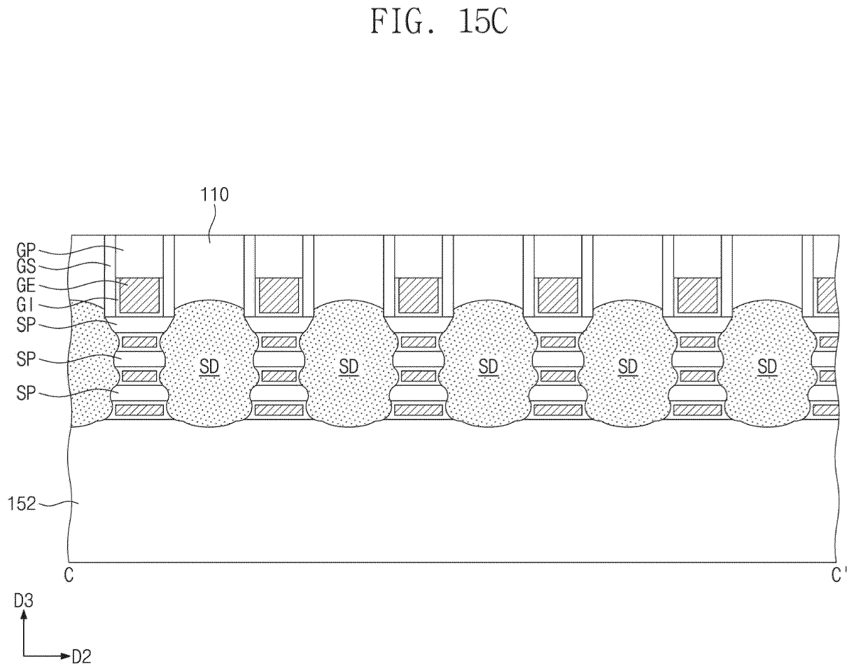

Referring to FIGS. 15A, 15B and 15C, the first sacrificial substrate 141, the second sacrificial substrate 142, and a lower portion 151 of the substrate 150 may be removed. Removing the first sacrificial substrate 141, the second sacrificial substrate 142 and the lower portion 151 of the substrate 150 may include at least one of performing a wet etching process or performing a chemical mechanical polishing process.

A lower portion of the preliminary interposed portion pIN of the device isolation layer 101 and lower portions of the fin patterns 152 may be removed. The lower portion of the preliminary interposed portion pIN of the device isolation layer 101 and the lower portions of the fin patterns 152 may be removed by, for example, a chemical mechanical polishing process. According to some embodiments, the lower portion 151 of the substrate 150, the lower portion of the preliminary interposed portion pIN of the device isolation layer 101 and the lower portions of the fin patterns 152 may be removed in one process.

The lower portion of the preliminary interposed portion pIN of the device isolation layer 101 may be removed to expose lower surfaces 103_L of the etch stop patterns 103. The fin patterns 152 may be separated by removing the lower portion 151 of the substrate 150. The lower portion 151 of the substrate 150 may be removed to expose lower surfaces of the fin patterns 152.

The preliminary interposed portion pIN in which a lower portion thereof is removed may be defined as an interposed portion IN. The interposed portion IN may include an upper portion UP, a first lower portion LP1 and a second lower portion LP2. Lower surfaces of the first lower portion LP1 and the second lower portion LP2 of the interposed portion IN may be exposed. The lower surfaces of the first lower portion LP1 and the second lower portion LP2 of the interposed portion IN may be coplanar with the lower surface 103_L of the etch stop pattern 103 and the lower surface of the fin pattern 152.

The etch stop pattern 103 may protect the upper portion UP of the interposed portion IN in a process of removing the lower portion of the substrate 150, the lower portion of the preliminary interposed portion pIN and the lower portions of the fin patterns 152.

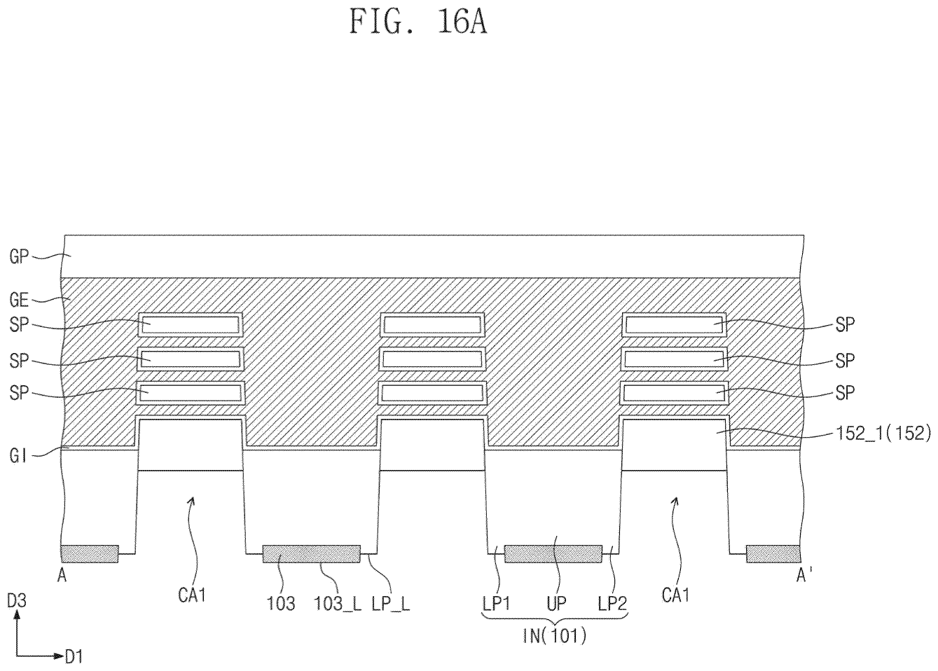

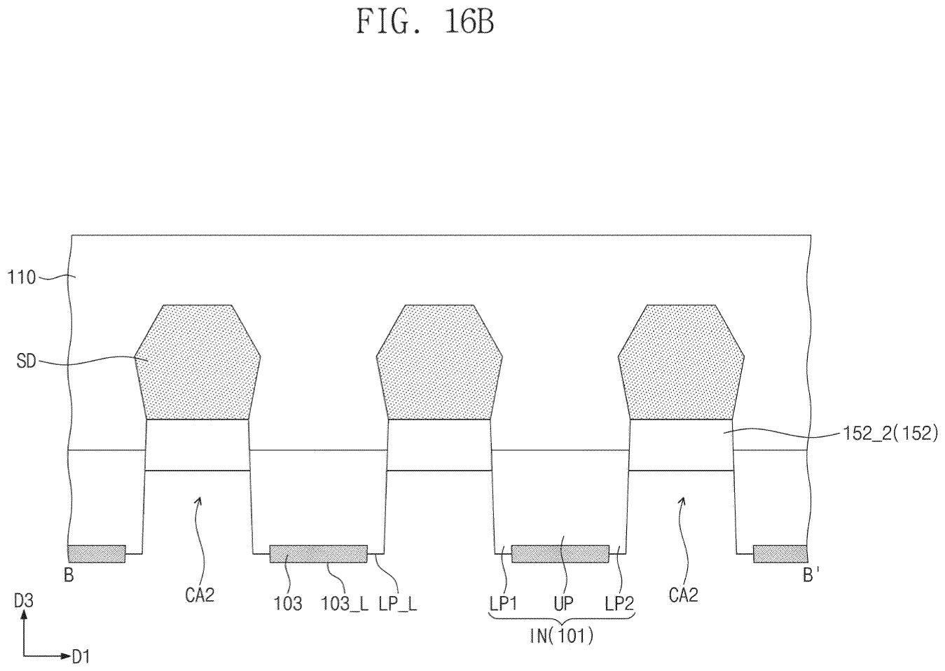

Referring to FIGS. 16A and 16B, the fin patterns 152 may be etched.

According to some embodiments, first parts 152_1 overlapping the gate electrode GE of the fin patterns 152 in the third direction D3 and second parts 152_2 overlapping the source/drain patterns SD in the third direction D3 may be etched. Each of the first parts 152_1 of the fin patterns 152 may be etched to form a first cavity CA1. Each of the second parts 152_2 of the fin patterns 152 may be etched to form a second cavity CA2. The first cavity CA1 may be disposed between the interposed portions IN adjacent to each other in the first direction D1. The second cavity CA2 may be disposed between the interposed portions IN adjacent to each other in the first direction D1. The first cavity CA1 may be defined by surfaces of the interposed portions IN and the first part 152_1 of the fin patterns 152. The second cavity CA2 may be defined by surfaces of the interposed portions IN and the second part 152_2 of the fin patterns 152.

Lower portions LP1 and LP2 of the interposed portion IN may be etched in an etching process of the fin patterns 152. The lower portions LP1 and LP2 of the interposed portion IN may be etched so that levels of lower surfaces LP_L of the lower portions LP1 and LP2 of the interposed portion IN may be higher than a level of the lower surface 103_L of the etch stop pattern 103.

Before the etching process of the fin patterns 152, a pre-clean process may be performed. For example, the pre-clean process may include supplying HF onto the lower surface of the fin patterns 152.

The etch stop pattern 103 may prevent the upper portion UP of the interposed portion IN from being etched in the pre-clean process and the process of forming the first and second cavities CA1 and CA2.

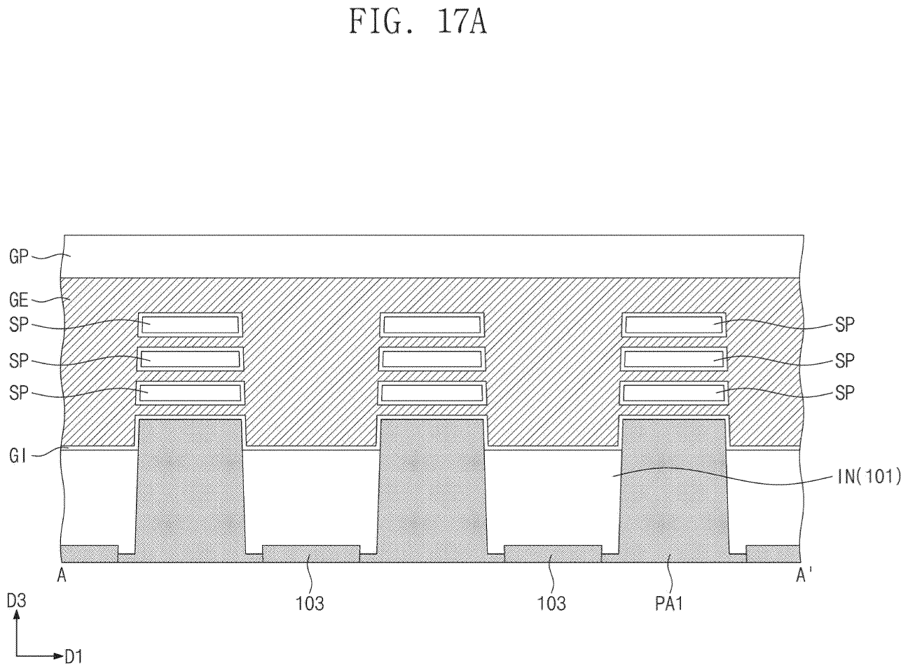

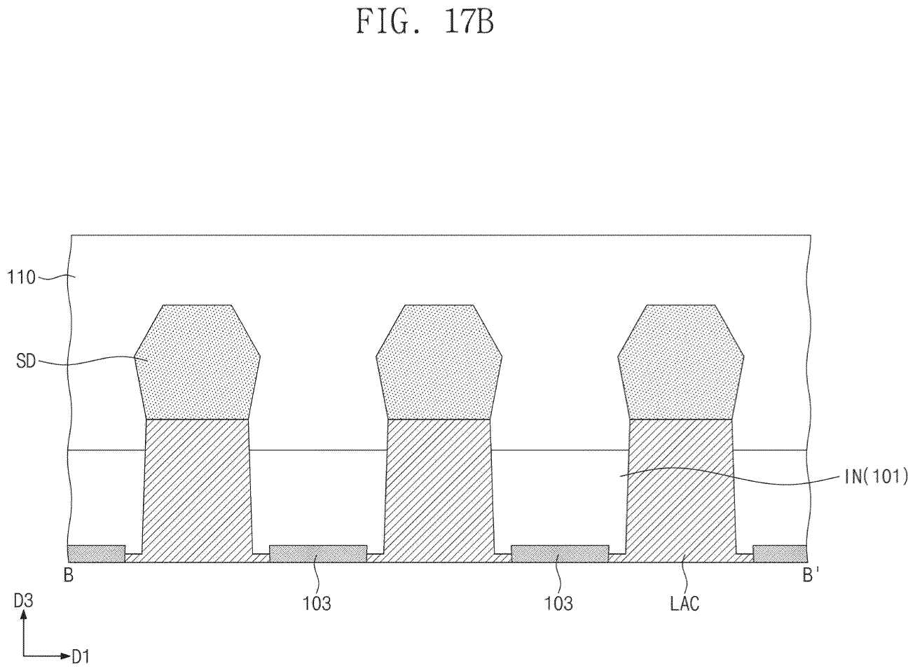

Referring to FIGS. 17A and 17B, the first parts 152_1 of the fin patterns 152 may be removed through the first cavities CA1. First patterns PA1 may be formed in the first cavities CA1 and empty spaces formed by removing the first parts 152_1 of the fin patterns 152.

The second parts 152_2 of the fin patterns 152 may be removed through the second cavities CA2. A lower active contact LAC may be formed in each of the second cavities CA2 and empty spaces formed by removing the second parts 152_2 of the fin patterns 152.

According to some embodiments, the first cavities CA1 and the second cavities CA2 may be simultaneously formed, and then the first parts 152_1 and the second parts 152_2 of the fin patterns 152 may be simultaneously removed. Thereafter, the first patterns PA1 and the lower active contacts LAC may be formed.

According to some embodiments, after the first cavities CA1 are formed and the first parts 152_1 of the fin patterns 152 are removed, the first patterns PA1 may be formed. After the second cavities CA2 are formed and the second parts 152_2 of the fin patterns 152 are removed, the lower active contacts LAC may be formed.

According to some embodiments, after the second cavities CA2 are formed and the second parts 152_2 of the fin pattern 152 are removed, the lower active contacts LAC may be formed. Thereafter, after the first cavities CA1 are formed and the first parts 152_1 of the fin patterns 152 are removed, the first patterns PA1 may be formed.

According to some embodiments, the first parts 152_1 of the fin patterns 152 may be removed in one process. According to some embodiments, the second parts 152_2 of the fin patterns 152 may be removed in one process.

Each portion of the fin patterns 152 remaining after the first parts 152_1 and the second parts 152_2 of the fin patterns 152 are removed may be defined as a second pattern PA2 (see FIG. 3D).

The etch stop pattern 103 may prevent the upper portion UP of the interposed portion IN from being etched in the process of removing the first part 152_1 and the second part 152_2 of the fin pattern 152.

Referring to FIGS. 3A to 3F, a lower insulating layer 102 may be formed. Lower conductive patterns 104 may be formed in the lower insulating layer 102. A second interlayer insulating layer 120 may be formed. Upper active contacts UAC and gate contacts GC may be formed.

According to the method for manufacturing a semiconductor device according to some embodiments, because the etch stop pattern 103 is formed, the interposed portion IN of the device isolation layer 101 may be protected in the process of removing the lower portion 151 of the substrate 150, the lower portion of the preliminary interposed portion pIN and the lower portions of the fin patterns 152, in the pre-clean process and the process of forming the first and second cavities CA1 and CA2, and in the process of removing the first parts 152_1 and the second parts 152_2 of the fin patterns 152. Accordingly, a phenomenon that a void is formed in the interposed portion IN of the device isolation layer 101 and a phenomenon that a metal residue is formed in the void in the subsequent processes may be prevented or limited.

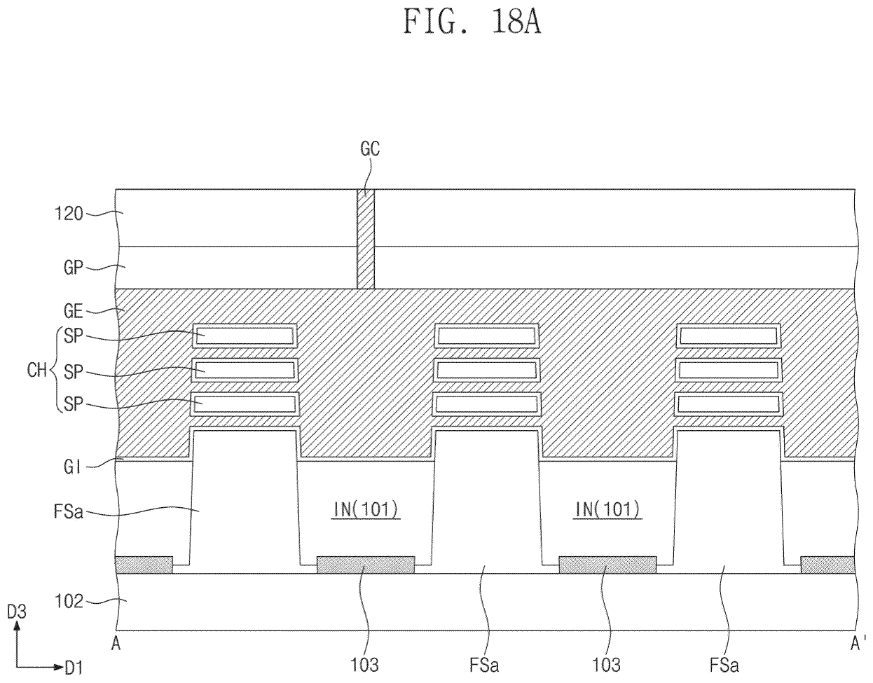

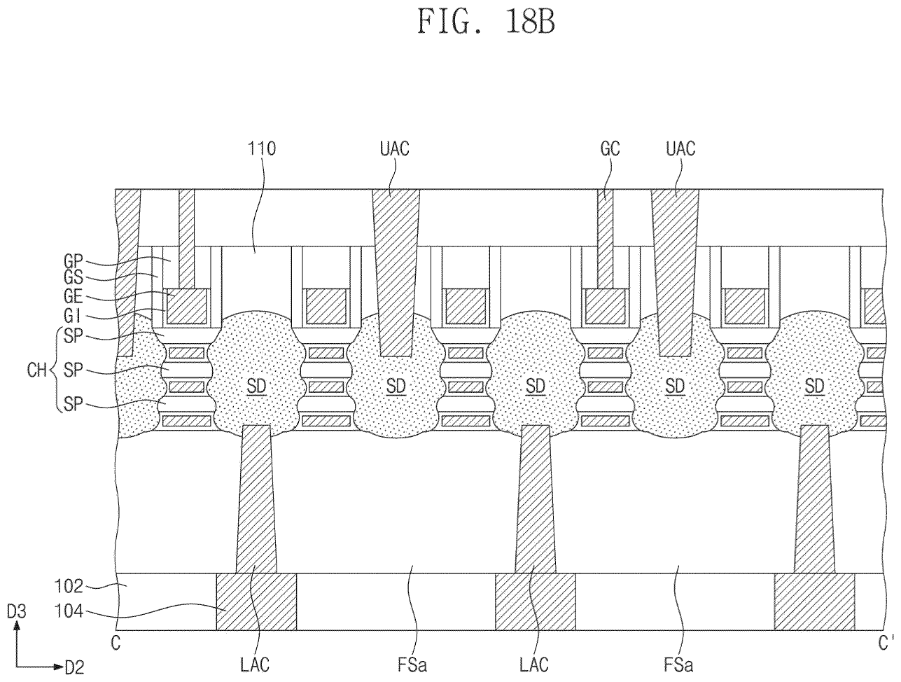

FIGS. 18A and 18B are cross-sectional views of a semiconductor device according to some embodiments. The semiconductor device according to FIGS. 18A and 18B may be similar to the semiconductor device according to FIGS. 3A to 3F except for what is described below. FIG. 18A may correspond to FIG. 3B. FIG. 18B may correspond to FIG. 3D.

Referring to FIGS. 18A and 18B, fin structures FSa may be insulating structures extending in the second direction D2. For example, the insulating structures may include a nitride. A plurality of source/drain patterns SD may be provided on the insulating structures. A plurality of channel structures CH and a plurality of gate electrodes GE may overlap the insulating structures in the third direction D3.

The fin patterns 152 may be completely removed (see FIGS. 15A, 15B and 15C), and then the insulating structure may be formed in empty spaces formed by removing the fin patterns 152.

According to some embodiments, the fin structures FSa may be single-crystalline semiconductor structures extending in the second direction D2. The single-crystalline semiconductor structures may include, for example, single-crystalline silicon. A plurality of source/drain patterns SD may be provided on the single-crystalline semiconductor structures. The plurality of channel structures CH and the plurality of gate electrodes GE may overlap the single-crystalline semiconductor structures in the third direction D3.

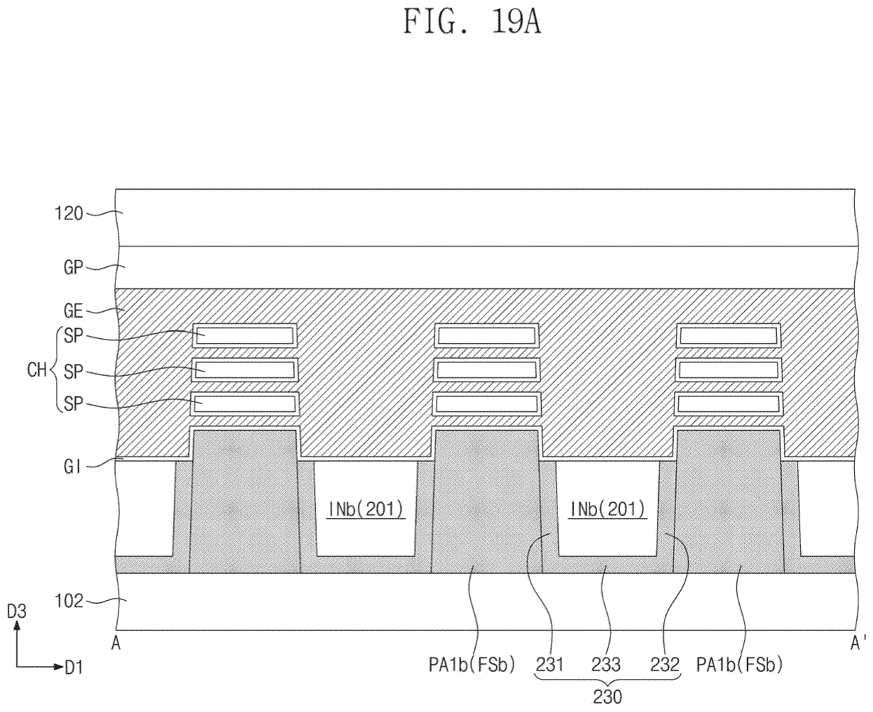

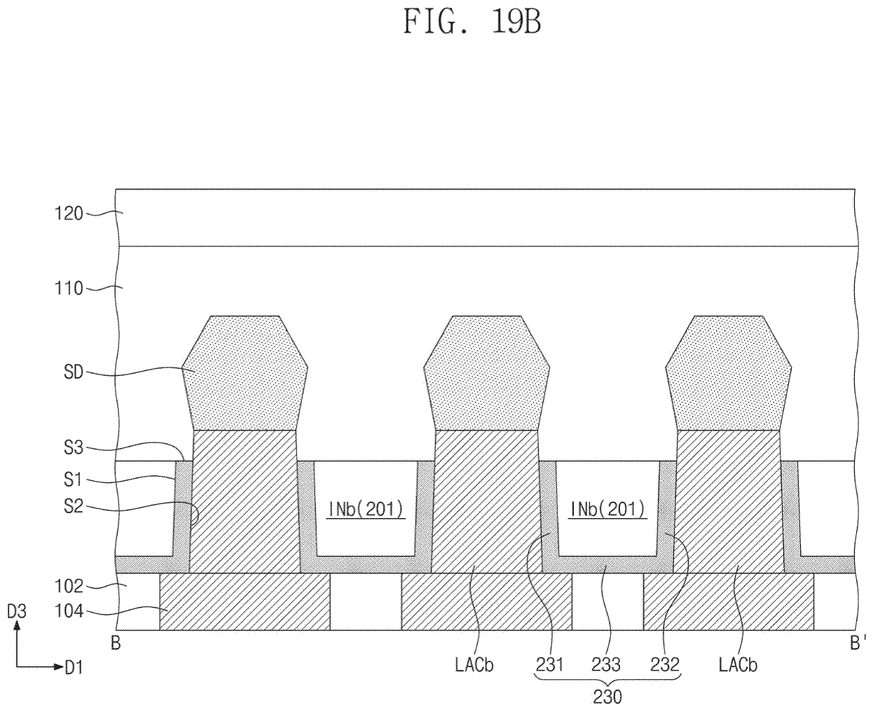

FIGS. 19A and 19B are cross-sectional views of a semiconductor device according to some embodiments. The semiconductor device according to FIGS. 19A and 19B may be similar to the semiconductor device according to FIGS. 3A to 3F except for what is described below. FIG. 19A may correspond to FIG. 3B. FIG. 19B may correspond to FIG. 3C.

Referring to FIGS. 19A and 19B, an etch stop pattern 230 may include a first part 231, a second part 232 and a third part 233. The first part 231 and the second part 232 of the etch stop pattern 230 may be spaced apart from each other in the first direction D1. The third part 233 of the etch stop pattern 230 may be disposed between the first part 231 and the second part 232 of the etch stop pattern 230. The third part 233 of the etch stop pattern 230 may connect the first part 231 and the second part 232 of the etch stop pattern 230.

A first pattern PA1b of a fin structure FSb may be spaced apart from an interposed portion INb of a device isolation layer 201. The first part 231 or the second part 232 of the etch stop pattern 230 may be interposed between the first pattern PA1b of the fin structure FSb and the interposed portion INb of the device isolation layer 201.

A lower active contact LACb may be spaced apart from the interposed portion INb of the device isolation layer 201. The first part 231 or the second part 232 of the etch stop pattern 230 may be interposed between the lower active contact LACb and the interposed portion INb of the device isolation layer 201.

The interposed portion INb of the device isolation layer 201 may be spaced apart from the lower insulating layer 102 and the lower conductive pattern 104.

Each of the first part 231 and the second part 232 of the etch stop pattern 230 may include a first sidewall S1 in contact with a sidewall of the interposed portion INb, and a second sidewall S2 in contact with a sidewall of the first pattern PA1b and a sidewall of the lower active contact LACb. Each of the first part 231 and the second part 232 of the etch stop pattern 230 may include an upper surface S3 in contact with the gate insulating layer GI and the first interlayer insulating layer 110. A lower surface of the third part 233 of the etch stop pattern 230 may be in contact with an upper surface of the lower insulating layer 102.

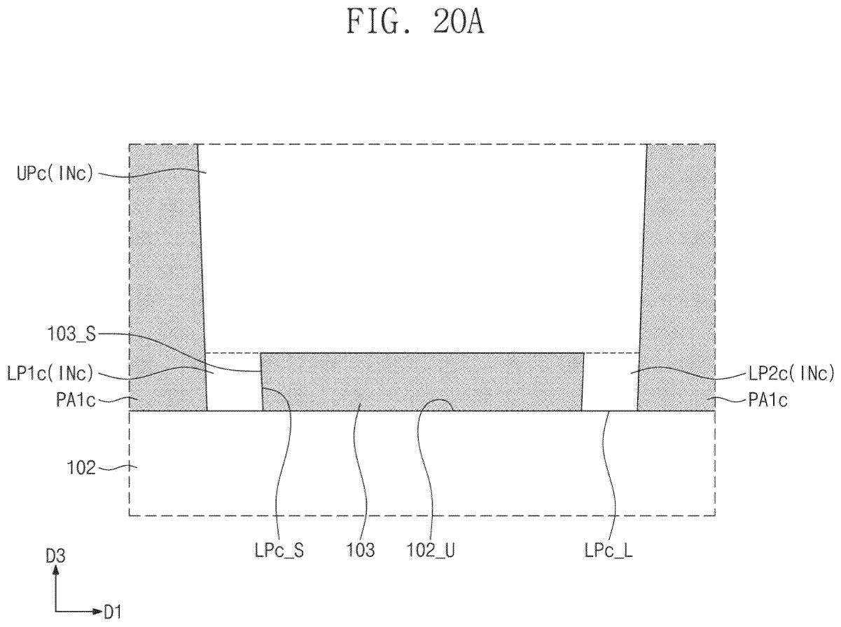

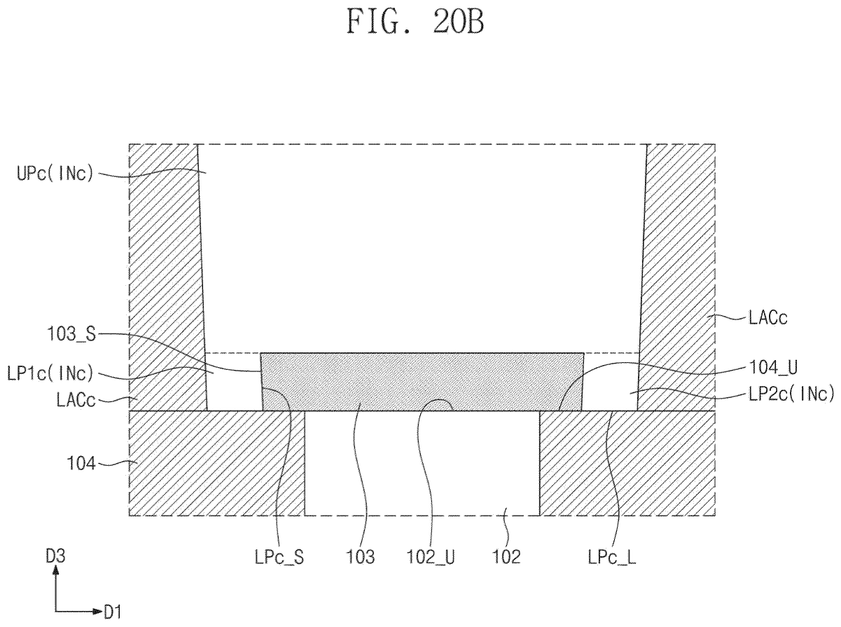

FIGS. 20A and 20B are enlarged cross-sectional views of a semiconductor device according to some embodiments. The semiconductor device according to FIGS. 20A and 20B may be similar to the semiconductor device according to FIGS. 3A to 3F except for what is described below. FIG. 20A may correspond to FIG. 3E. FIG. 20B may correspond to FIG. 3F.

Referring to FIGS. 20A and 20B, an interposed portion INc may include a first lower portion LP1c, a second lower portion LP2c and an upper portion UPc. A lower surface LPc_L of each of the first lower portion LP1c and the second lower portion LP2c of the interposed portion INc may be in contact with an upper surface 102_U of the lower insulating layer 102 and an upper surface 104_U of the lower conductive pattern 104.

A first pattern PA1c and a lower active contact LACc may be spaced apart from the etch stop pattern 103. A first lower portion LP1c or a second lower portion LP2c of the interposed portion INc may be interposed between the first pattern PA1c and the etch stop pattern 103. A sidewall 103_S of the etch stop pattern 103 may be in contact with all of a sidewall LPc_S of the lower portion LP1c or LP2c of the interposed portion INc.

A semiconductor device according to embodiments includes an etch stop pattern, and thus an interposed portion of a device isolation layer may be protected and reliability of the semiconductor device may be improved.

While aspects of embodiments have been particularly shown and described, it will be understood that various changes in form and details may be made therein without departing from the spirit and scope of the following claims.

What is claimed is:

1. A semiconductor device comprising:
a first fin structure extending in a vertical direction;
a second fin structure extending in the vertical direction, wherein the second fin structure is spaced apart from the first fin structure;
an etch stop pattern between the first fin structure and the second fin structure;
a lower insulating layer in contact with a lower surface of the first fin structure, a lower surface of the second fin structure and a lower surface of the etch stop pattern;
a device isolation layer comprising an interposed portion on the etch stop pattern, between the first fin structure and the second fin structure;
a gate electrode overlapping the interposed portion and the first fin structure;
a channel structure overlapping the gate electrode; and
a source/drain pattern connected to the channel structure,
wherein the etch stop pattern comprises a different insulating material from the device isolation layer.

2. The semiconductor device of claim 1, wherein the interposed portion comprises an upper portion and a first lower portion,
wherein the upper portion of the interposed portion is in contact with an upper surface of the etch stop pattern, and
wherein a sidewall of the first lower portion of the interposed portion is in contact with a sidewall of the etch stop pattern.

3. The semiconductor device of claim 2, wherein a level of a lower surface of the first lower portion of the interposed portion is farther from the lower insulating layer than a level of the lower surface of the etch stop pattern.

4. The semiconductor device of claim 2, wherein a lower surface of the first lower portion of the interposed portion is in contact with the first fin structure.

5. The semiconductor device of claim 2, wherein the interposed portion further comprises a second lower portion, and
wherein the etch stop pattern is between the first and second lower portions of the interposed portion.

6. The semiconductor device of claim 2, wherein the first fin structure comprises a portion in contact with the sidewall of the etch stop pattern and a lower surface of the first lower portion of the interposed portion.

7. The semiconductor device of claim 1, wherein the first fin structure and the second fin structure are spaced apart from each other in a first direction, and
wherein a width in the first direction of the etch stop pattern is less than a width in the first direction of the interposed portion.

8. The semiconductor device of claim 1, wherein the first fin structure comprises a first pattern overlapping the gate electrode and the channel structure, and a second pattern overlapping the source/drain pattern,
wherein the first pattern comprises an insulating material, and
wherein the second pattern comprises a different material from the first pattern.

9. A semiconductor device comprising:
a first fin structure extending in a vertical direction;
a second fin structure extending in the vertical direction, wherein the second fin structure is spaced apart from the first fin structure in a first direction;
an etch stop pattern between the first fin structure and the second fin structure;
a device isolation layer comprising an interposed portion on the etch stop pattern, between the first fin structure and the second fin structure;
a gate electrode overlapping the interposed portion and the first fin structure;
a channel structure overlapping the gate electrode;
a source/drain pattern on the first fin structure; and
a lower active contact connected to the source/drain pattern via the first fin structure,
wherein the etch stop pattern comprises a different insulating material from the device isolation layer.

10. The semiconductor device of claim 9, wherein the first fin structure comprises a first pattern overlapping the gate electrode and a second pattern overlapping the source/drain pattern,
wherein the first pattern and the second pattern respectively comprise different materials from each other, and
wherein the lower active contact penetrates the second pattern.

11. The semiconductor device of claim 10, wherein the first pattern comprises an insulating material, and
wherein the second pattern comprises a semiconductor material.

12. The semiconductor device of claim 9, wherein the lower active contact comprises a first part in contact with a sidewall of the interposed portion, and a second part in contact with a sidewall of the etch stop pattern.

13. The semiconductor device of claim 12, wherein an upper surface of the second part of the lower active contact is in contact with a lower surface of the interposed portion.

14. The semiconductor device of claim 9, further comprising a lower insulating layer in contact with a lower surface of the first fin structure, a lower surface of the second fin structure and a lower surface of the etch stop pattern.

15. The semiconductor device of claim 14, further comprising a lower conductive pattern in the lower insulating layer,
wherein an upper surface of the lower conductive pattern is in contact with a lower surface of the lower active contact.

16. The semiconductor device of claim 15, wherein the upper surface of the lower conductive pattern is in contact with the lower surface of the etch stop pattern.

17. The semiconductor device of claim 9, wherein the interposed portion comprises a lower portion between the etch stop pattern and the lower active contact, and
wherein the lower portion of the interposed portion and the etch stop pattern overlap along the first direction.

18. A semiconductor device comprising:
a lower insulating layer;
a lower conductive pattern in the lower insulating layer;
a first fin structure and a second fin structure on the lower insulating layer and extending in a vertical direction;
an etch stop pattern between the first fin structure and the second fin structure;
a device isolation layer comprising an interposed portion on the etch stop pattern, between the first fin structure and the second fin structure;
a gate electrode overlapping the interposed portion and the first fin structure;
a channel structure overlapping the gate electrode;
a source/drain pattern on the first fin structure; and
a lower active contact electrically connecting the source/drain pattern and the lower conductive pattern,
wherein a lower surface of the first fin structure, a lower surface of the second fin structure and a lower surface of the etch stop pattern are in contact with an upper surface of the lower insulating layer.

19. The semiconductor device of claim 18, wherein the etch stop pattern is spaced apart from each of the first fin structure, the second fin structure and the lower active contact.

20. The semiconductor device of claim 19, wherein the interposed portion comprises a lower portion between the lower active contact and the etch stop pattern, and an upper portion in contact with an upper surface of the etch stop pattern, and
wherein a lower surface of the lower portion of the interposed portion is in contact with the upper surface of the lower insulating layer.
